(19) United States
(12) Patent Application Publication
(10) Pub. No.: US 2019/0071571 A1
(43) Pub. Date: Mar. 7, 2019

(54) COLORING COMPOSITION, DICHROIC DYE COMPOUND, LIGHT ABSORPTION ANISOTROPIC FILM, LAMINATE, AND IMAGE DISPLAY DEVICE

(71) Applicant: FUJIFILM Corporation, Tokyo (JP)

(72) Inventors: Yoshiaki TAKADA, Kanagawa (JP); Wataru HOSHINO, Kanagawa (JP); Ryoji GOTO, Kanagawa (JP); Jyunko IBARAKI, Kanagawa (JP); Hiroshi MATSUYAMA, Kanagawa (JP); Masatoshi MIZUMURA, Kanagawa (JP)

(73) Assignee: FUJIFILM Corporation, Tokyo (JP)

(21) Appl. No.: 16/183,011

(22) Filed: Nov. 7, 2018

Related U.S. Application Data
(63) Continuation of application No. PCT/JP2017/017718, filed on May 10, 2017.

(30) Foreign Application Priority Data
May 12, 2016 (JP) 2016-095907
Dec. 28, 2016 (JP) 2016-255416

(51) Int. Cl. C09B 31/20; B32B 27/20; B32B 27/08; C09B 31/062; G02F 1/1335; G02B 5/30; H01L 51/52

(52) U.S. Cl. CPC C09B 31/20; B32B 27/20; B32B 27/08; C09B 31/062; B32B 2457/202; G02B 5/3025; H01L 51/5281; B32B 2307/7244; G02F 1/133528

(57) ABSTRACT

A dichroic dye compound has an excellent alignment property when used in a light absorption anisotropic film, and has excellent solubility. A coloring composition contains the dichroic dye compound having a structure represented by Formula (1). In Formula (1), A and B represent a crosslinkable group, a and b are 0 or 1, and a+b is not less than 1. L₁ and L₂ represent a monovalent substituent, a single bond, or a divalent linking group. Each of Ar₁ to Ar₃ represents an aromatic hydrocarbon group or heterocyclic group. R₁ to R₃ represent a monovalent substituent. k represents an integer of 1 to 4. n1, n2, and n3 represent an integer of 0 to 4. In a case where k is 1, n1+n2+n3 is not less than 0, and in a case where k is not less than 2, n1+n2+n3 is not less than 1.

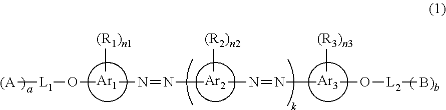

### CROSS-REFERENCE TO RELATED APPLICATIONS

This application is a Continuation of PCT International Application No. PCT/JP2017/017718 filed on May 10, 2017, which claims priority under 35 U.S.C. § 119(a) to Japanese Patent Application No. 2016-095907 filed on May 12, 2016 and Japanese Patent Application No. 2016-255416 filed on Dec. 28, 2016. Each of the above applications is hereby expressly incorporated by reference, in its entirety, into the present application.

### BACKGROUND OF THE INVENTION

### 1. Field of the Invention

The present invention relates to a coloring composition, a dichroic dye compound, a light absorption anisotropic film, a laminate, and an image display device.

### 2. Description of the Related Art

In a case where an attenuation function, a polarization function, a scattering function, or a shielding function is required in relation to irradiated light including laser light and natural light, a device which is operated by a different principle for each function has been used. Therefore, products corresponding to the above-described functions have also been manufactured through a different manufacturing process for each function.

For example, in liquid crystal displays (LCDs), a linearly polarizing plate or a circularly polarizing plate is used to control optical activity or a birefringent property in display. In addition, in organic light emitting diodes (OLEDs), a circularly polarizing plate is also used to prevent external light from being reflected.

Iodine has been widely used as a dichroic substance in these polarizing plates (polarizing elements). However, a polarizing element using an organic dye as a dichroic substance instead of iodine has also been examined.

In recent years, due to demands for a reduction in the thickness of polarizing elements, manufacturing a polarizing element by applying a coating solution containing an organic dye (dichroic dye compound) to a substrate has been examined. For example, JP2001-133630A describes forming an anisotropic film having polarizing ability by using a coating solution containing a dichroic dye compound (claim 2, paragraph 0008, etc.). In addition, JP2001-133630A discloses an azo dye having a specific structure as a dichroic dye compound (paragraphs 0009 and 0010, etc.).

### SUMMARY OF THE INVENTION

The inventors have examined the light absorption anisotropic film described in JP2001-133630A, and found that depending on the kind of the dichroic dye compound contained in the coloring composition used for the formation of the light absorption anisotropic film, the alignment degree of the light absorption anisotropic film may be reduced, or the solubility to a solvent may be reduced.

Particularly, the inventors have found that depending on the kind of the dichroic dye compound contained in the coloring composition, the solubility to cyclopentanone having high applicability may be low.

Accordingly, an object of the invention is to provide a dichroic dye compound having an excellent alignment property when being used in a light absorption anisotropic film, and having excellent solubility, a coloring composition, a light absorption anisotropic film, a laminate, and an image display device.

As a result of intensive studies about the above-described object, the inventors have found that using a dichroic dye compound having a specific structure makes it possible to obtain excellent solubility and obtain a light absorption anisotropic film having an excellent alignment property, and completed the invention.

That is, the inventors have found that the object can be achieved with the following configuration.

[1] A coloring composition comprising: a dichroic dye compound having a structure represented by Formula (1).

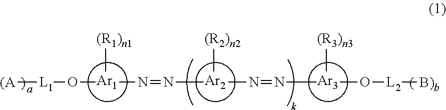

In Formula (1), A and B each independently represent a crosslinkable group.

In Formula (1), a and b each independently represent 0 or 1, and a+b is not less than 1.

In Formula (1), in a case where a is 0, L₁ represents a monovalent substituent, in a case where a is 1, L₁ represents a single bond or a divalent linking group, in a case where b is 0, L₂ represents a monovalent substituent, and in a case where b is 1, L₂ represents a single bond or a divalent linking group.

In Formula (1), Ar₁ represents a (n1+2)-valent aromatic hydrocarbon group or heterocyclic group, Ar₂ represents a (n2+2)-valent aromatic hydrocarbon group or heterocyclic group, and Ar₃ represents a (n3+2)-valent aromatic hydrocarbon group or heterocyclic group.

In Formula (1), R₁, R₂, and R₃ each independently represent a monovalent substituent, in a case where n1 is not less than 2, plural R₁'s may be the same or different, in a case where n2 is not less than 2, plural R₂'s may be the same or different, and in a case where n3 is not less than 2, plural R₃'s may be the same or different.

In Formula (I), k represents an integer of 1 to 4, and in a case where k is not less than 2, plural Ar₂'s may be the same or different, and plural R₂'s may be the same or different.

In Formula (1), n1, n2, and n3 each independently represent an integer of 0 to 4, in a case where k is 1, n1+n2+n3 is not less than 0, and in a case where k is not less than 2, n1+n2+n3 is not less than 1.

[2] The coloring composition according to [1], in which in Formula (1), in a case where Ar₁, Ar₂, and Ar₃ have a condensed ring structure, all rings constituting the condensed ring structure are connected along a longitudinal direction of the structure represented by Formula (1).

[3] The coloring composition according to [1] or [2], in which in a case where Formula (1) has at least one substituent selected from R₁, R₂ or R₃, at least one condition selected from the following condition (R1), (R2), or (R3) is satisfied.

Condition (R1): in Ar₁, at least one R₁ and an azo group are positioned next to each other.

Condition (R2): in Ar₂, at least one R₂ and at least one azo group are positioned next to each other.

Condition (R3): in Ar₃, at least one R₃ and an azo group are positioned next to each other.

[4] The coloring composition according to any one of [1] to [3], in which in a case where Formula (1) has at least one substituent selected from R₁, R₂ or R₃, the monovalent substituent represented by R₁, the monovalent substituent represented by R₂, and the monovalent substituent represented by R₃ each independently represent a halogen atom, a cyano group, a hydroxy group, an alkyl group, an alkoxy group, a fluorinated alkyl group, —O—(C₂H₄O)m-R′, —O—(C₃H₆O)m-R′, an alkylthio group, an oxycarbonyl group, a thioalkyl group, an acyloxy group, an acylamino group, an alkoxycarbonylamino group, a sulfonylamino group, a sulfamoyl group, a carbamoyl group, a sulfinyl group, or a ureido group, R′ represents a hydrogen atom, a methyl group, or an ethyl group, and m represents an integer of 1 to 6.

[5] The coloring composition according to any one of [1] to [4], in which in Formula (1), the number of atoms of a main chain of at least one of L₁ or L₂ is 3 or more.

[6] The coloring composition according to any one of [1] to [5], in which the crosslinkable group is an acryloyl group or a methacryloyl group.

[7] The coloring composition according to any one of [1] to [6], further comprising: one or more kinds of dichroic dye compounds other than the dichroic dye compound having a structure represented by Formula (1).

[8] A dichroic dye compound having a structure represented by Formula (1).

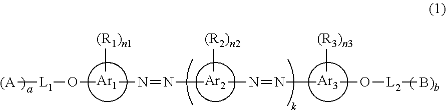

In Formula (1), A and B each independently represent a crosslinkable group.

In Formula (1), a and b each independently represent 0 or 1, and a+b is not less than 1.

In Formula (1), in a case where a is 0, L₁ represents a monovalent substituent, in a case where a is 1, L₁ represents a single bond or a divalent linking group, in a case where b is 0, L₂ represents a monovalent substituent, and in a case where b is 1, L₂ represents a single bond or a divalent linking group.

In Formula (1), Ar₁ represents a (n1+2)-valent aromatic hydrocarbon group or heterocyclic group, Ar₂ represents a (n2+2)-valent aromatic hydrocarbon group or heterocyclic group, and Ar₃ represents a (n3+2) -valent aromatic hydrocarbon group or heterocyclic group.

In Formula (1), R₁, R₂, and R₃ each independently represent a monovalent substituent, in a case where n1 is not less than 2, plural R₁'s may be the same or different, in a case where n2 is not less than 2, plural R₂'s may be the same or different, and in a case where n3 is not less than 2, plural R₃'s may be the same or different.

In Formula (1), k represents an integer of 1 to 4, and in a case where k is not less than 2, plural Ar₂'s may be the same or different, and plural R₂'s may be the same or different,

In Formula (1), n1, n2, and n3 each independently represent an integer of 0 to 4, in a case where k is 1, n1+n2+n3 is not less than 0, and in a case where k is not less than 2, n1+n2+n3 is not less than 1.

[9] The dichroic dye compound according to [8], in which in Formula (1), in a case where Ar₁, Ar₂, and Ar₃ have a condensed ring structure, all rings constituting the condensed. ring structure are connected along a longitudinal direction of the structure represented by Formula (1).

[10] The dichroic dye compound according to [8] or [9], in which in a case where Formula (1) has at least one substituent selected from R₁, R₂ or R₃, at least one condition selected from the following condition (R1), (R2), or (R3) is satisfied.

Condition (R1): in Ar₁, at least one R₁ and an azo group are positioned next to each other.

Condition (R2): in Ar₂, at least one R₂ and at least one azo group are positioned next to each other.

Condition (R3): in at least one R₃ and an azo group are positioned next to each other.

[11] The dichroic dye compound according to any one of [8] to [10], in which in a case where Formula (1) has at least one substituent selected from R₁, R₂ or R₃, the monovalent substituent represented by the monovalent substituent represented by R₂, and the monovalent substituent represented by R₃ each independently represent a halogen atom, a cyano group, a hydroxy group, an alkyl group, an alkoxy group, a fluorinated alkyl group, —O—(C₂H₄O)m-R′, —O—(C₃H₆O)m-R′, an alkylithio group, an oxycarbonyl group, a thioalkyi group, an a.cyloxy group, an acylamino group, an alkoxycarbonylamino group, a sulfonylamino group, a sulfamoyl group, a carbamoyl group, a sulfinyl group, or a ureido group, R′ represents a hydrogen atom, a methyl group, or an ethyl group, and m represents an integer of 1 to 6.

[12] The dichroic dye compound according to any one of [8] to [11], in which in Formula (1), the number of atoms of a main chain of at least one of L₁ or L₂ is 3 or more.

[13] The dichroic dye compound according to any one of [8] to [12], in which the crosslinkable group is an acryloyl group or a methaeryloyl group.

[14] A light absorption anisotropic film which is formed using the coloring composition according to any one of [1] to [7].

[15] A laminate comprising: a base; and the light absorption anisotropic film according to [14] which is formed on the base.

[16] The laminate according to [15], further comprising: a λ/4 plate which is formed on the light absorption anisotropic film.

[17] The laminate according to [15], further comprising: an oxygen blocking layer which is formed on the light absorption anisotropic film.

[18] An image display device comprising: the light absorption anisotropic film according to [14]; or the laminate according to any one of [15] to [17].

As described above, according to the embodiment of the invention, it is possible to provide a dichroic dye compound having an excellent alignment property when being used in a light absorption anisotropic film, and having excellent solubility, a coloring composition, a light absorption anisotropic film, a laminate, and an image display device.

### DESCRIPTION OF THE PREFERRED EMBODIMENTS

Hereinafter, the invention will be described.

The following description of constituent requirements is based on typical embodiments of the invention, but the invention is not limited thereto.

In the invention, a numerical value range expressed using “to” means a range including numerical values before and after “to” as a lower limit value and an upper limit value.

[Coloring Composition]

A coloring composition according to the embodiment of the invention contains a dichroic dye compound having a structure represented by Formula (1) (hereinafter, also simply referred to as “specific dichroic dye compound”).

The specific dichroic dye compound contained in the coloring composition according to the embodiment of the invention has a structure represented by Formula (1), and thus has excellent solubility to a solvent. Therefore, since a solvent having excellent applicability such as cyclopentanone can be used, a light absorption anisotropic film having such a film thickness that the film exhibits desired optical characteristics is easily obtained.

Here, the inventors have found that in a case where a dichroic dye compound having a trisazo structure (including three azo groups) represented by (a) in JP2001-133630A is used (corresponding to a dichroic dye compound D12 in examples to be described later), the solubility to a solvent deteriorates.

The inventors have performed examination based on such knowledge, and found that in a case where Formula (1) to be described later has a trisazo structure, a tetrakisazo structure (a structure including four azo groups), or a pentakisazo structure (a structure including five azo groups), solubility is improved by introducing at least one substituent (R₁ to R₃) to Ar₁ to Ar₃. The reason for this is thought to be that due to the substituent existing in a direction (lateral direction) intersecting with a longitudinal direction in which molecules of the specific dichroic dye compound extend, dense overlapping between molecules of the specific dichroic dye compound is inhibited, and the molecules easily interact with solvent molecules.

In addition, the inventors have found that in a case where the number of rings bonded to azo groups is reduced by reducing the number of the azo groups (that is, from a structure including three or more azo groups to a bisazo structure including two azo groups), the solubility of the dichroic dye compound can be improved. The reason for this is thought to be that in the bisazo structure, overlapping between molecules is smaller than in a structure including three or more azo groups, and thus the molecules easily interact with solvent molecules.

In addition, according to the coloring composition according to the embodiment of the invention, a light absorption anisotropic film having an excellent alignment property can be formed in a case where the specific dichroic dye compound is contained.

Hereinafter, components contained in the coloring composition according to the embodiment of the invention and components which can be contained will be described.

<Specific Dichroic Dye Compound>

The coloring composition according to the embodiment of the invention contains a specific dichroic dye compound. The specific dichroic dye compound refers to a dichroic dye compound having a structure represented by Formula (1) as described above.

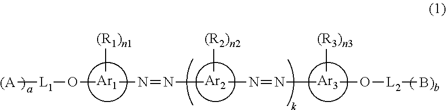

in Formula (1), A and B each independently represent a crosslinkable group.

In Formula (1), a and b each independently represent 0 or 1. a+b is not less than 1.

In Formula (1), in a case where a is 0, L₁ represents a monovalent substituent, and in a case where a is 1, L₁ represents a single bond or a divalent linking group. In addition, in a case where b is 0, L₂ represents a monovalent substituent, and in a case where b is 1, L₂ represents a single bond or a divalent linking group.

In Formula (1), Ar₁ represents a (n1+2)-valent aromatic hydrocarbon group or heterocyclic group, Ar₂ represents a (n2+2)-valent aromatic hydrocarbon group or heterocyclic group, and Ar₃ represents a (n3+2) -valent aromatic hydrocarbon group or heterocyclic group.

In Formula (1), R₁, R₂, and R₃ each independently represent a monovalent substituent. In a case where n1 is not less than 2, plural R₁'s may be the same or different. In a case where n2 is not less than 2, plural R₂'s may be the same or different. In a case where n3 is not less than 2, plural R₃'s may be the same or different.

In Formula (1), k represents an integer of 1 to 4. In a case where k is not less than 2, plural Ar₂'s may be the same or different, and plural R₂'s may be the same or different.

In Formula (1), n1, n2, and n3 each independently represent an integer of 0 to 4. In a case where k is 1, n1+n2+n3 is not less than 0, and in a case where k is not less than 2, n1+n2+n3 is not less than 1.

In Formula (1), examples of the crosslinkable group represented by A or B include polymerizable groups described in paragraphs [0040] to [0050] of JP2010-244038A. Among these, an acryloyl group, a methacryloyl group, an epoxy group, an oxetanyl group, and a styryl group are preferable from the viewpoint of an improvement in reactivity and synthesis suitability, and an acryloyl group and a methacryloyl group are more preferable from the viewpoint of a further improvement in solubility.

In Formula (1), a and b each independently represent 0 or 1, and a+b is not less than 1. That is, the specific dichroic dye compound has at least one crosslinkable group at a terminal.

Here, it is preferable that both a and b be 1, that is, a crosslinkable group be introduced at both terminals of the specific dichroic dye compound. This is advantageous in that the solubility of the specific dichroic dye compound is further improved and the durability of the light absorption anisotropic film is improved.

In Formula (1), in a case where a is 0, L₁ represents a monovalent substituent, and in a case where a is 1, L₁ represents a single bond or a divalent linking group. In addition, in a case where b is 0, L₂ represents a monovalent substituent, and in a case where b is 1, L₂ represents a single bond or a divalent linking group.

Both L₁ and L₂ are preferably single bonds or divalent linking groups, and preferably divalent linking groups. Thanks to this, the solubility of the specific dichroic dye compound is further improved.

As the monovalent substituent represented by L₁ or L₂, a group which is introduced to increase the solubility of the dichroic dye compound, or an electron-donating or electron-withdrawing group which is introduced to adjust a tone as a dye is preferable.

As the substituent, an alkyl group(preferably having 1 to 20 carbon atoms, more preferably 1 to 12 carbon atoms, and particularly preferably 1 to 8 carbon atoms, exemplified by a methyl group, an ethyl group, an isopropyl group, a tert-butyl group, an n-octyl group, an n-decyl group, an n-hexadecyl group, a cyclopropyl group, a cyclopentyl group, and a cyclohexyl group),

an alkenyl group (preferably having 2 to 20 carbon atoms, more preferably 2 to 12 carbon atoms, and particularly preferably 2 to 8 carbon atoms, exemplified by a vinyl group, an allyl group, a 2-butenyl group, and a 3-pentenyl group),

an alkynyl group (preferably having 2 to 20 carbon atoms, more preferably 2 to 12 carbon atoms, and particularly preferably 2 to 8 carbon atoms, exemplified by a propargyl group and a 3-pentynyl group),

an aryl group (preferably having 6 to 30 carbon atoms, more preferably 6 to 20 carbon atoms, and particularly preferably 6 to 12 carbon atoms, exemplified by a phenyl group, a 2,6-diethylphenyl group, a 3,5-ditrifluoromethylphenyl group, a naphthyl group, and a biphenyl group),

a substituted or unsubstituted amino group (preferably having 0 to 20 carbon atoms, more preferably 0 to 10 carbon atoms, and particularly preferably 0 to 6 carbon atoms, exemplified by an unsubstituted amino group, a methylamino group, a dimethylamino group, a diethylamino group, and an anilino group),

an alkoxy group (preferably having 1 to 20 carbon atoms, and more preferably 1 to 15 carbon atoms, exemplified by a methoxy group, an ethoxy group, and a butoxy group),

an oxycarbonyl group (preferably having 2 to 20 carbon atoms, more preferably 2 to 15 carbon atoms, and particularly preferably 2 to 10 carbon atoms, exemplified by a methoxycarbonyl group, an ethoxycarbonyl group, and a phenoxycarbonyl group),

an acyloxy group (preferably having 2 to 20, more preferably 2 to 10 carbon atoms, and particularly preferably 2 to 6 carbon atoms, exemplified by an acetoxy group and a benzoyloxy group),

an acyl amino group (preferably having 2 to 20 carbon atoms, more preferably 2 to 10 carbon atoms, and particularly preferably 2 to 6 carbon atoms, exemplified by an acetylamino group and a benzoylamino group),

an alkoxycarbonylamino group (preferably having 2 to 20 carbon atoms, more preferably 2 to 10 carbon atoms, and particularly preferably 2 to 6 carbon atoms, exemplified by a methoxycarbonylamino group),

an aryloxycarbonylamino group (preferably having 7 to 20 carbon atoms, more preferably 7 to 16 carbon atoms, and particularly preferably 7 to 12 carbon atoms, exemplified by a phenyloxycarbonylamino group),

a sulfonylamino group (preferably having 1 to 20 carbon atoms, more preferably 1 to 10 carbon atoms, and particularly preferably 1 to 6 carbon atoms, exemplified by a methanesulfonylamino group and a benzenesulfonylamino group),

a sulfamoyl group (preferably having 0 to 20 carbon atoms, more preferably 0 to 10 carbon atoms, and particularly preferably 0 to 6 carbon atoms, exemplified by an unsubstituted sulfamoyl group, a methylsulfamoyl group, a dimethylsulfamoyl group, and a phenylsulfamoyl group),

a carbamoyl group (preferably having 1 to 20 carbon atoms, more preferably 1 to 10 carbon atoms, and particularly preferably 1 to 6 carbon atoms, exemplified by an unsubstituted carbamoyl group, a methylcarbamoyl group, a diethylcarbamoyl group, and a phenylcarbamoyl group),

an alkylthio group (preferably having 1 to 20 carbon atoms, more preferably 1 to 10 carbon atoms, and particularly preferably 1 to 6 carbon atoms, exemplified by a methylthio group and an ethylthio group),

an arylthio group (preferably having 6 to 20 carbon atoms, more preferably 6 to 16 carbon atoms, and particularly preferably 6 to 12 carbon atoms, exemplified by a phenylthio group),

a sulfonyl group (preferably having 1 to 20 carbon atoms, more preferably 1 to 10 carbon atoms, and particularly preferably 1 to 6 carbon atoms, exemplified by a mesyl group and a tosyl group),

a sulfinyl group (preferably having 1 to 20 carbon atoms, more preferably 1 to 10 carbon atoms, and particularly preferably 1 to 6 carbon atoms, exemplified by a methanesulfinyl group and a benzenesulfinyl group),

a ureido group (preferably having 1 to 20 carbon atoms, more preferably 1 to 10 carbon atoms, and particularly preferably 1 to 6 carbon atoms, exemplified by an unsubstituted ureido group, a methylureido group, and a phenylureido group),

a phosphoric acid amide group (preferably having 1 to 20 carbon atoms, more preferably 1 to 10 carbon atoms, and particularly preferably 1 to 6 carbon atoms, exemplified by a diethylphosphoric acid amide group and a phenylphosphoric acid amide group),

a heterocyclic group (preferably having 1 to 30 carbon atoms, and more preferably 1 to 12 carbon atoms, which is a heterocyclic group having heteroatom(s) such as a nitrogen atom, an oxygen atom, and a sulfur atom, and is exemplified by an imidazolyl group, a pyridyl group, a quinolyl group, a furyl group, a piperidyl group, a morpholino group, a benzoxazolyl group, a benzimidazolyl group, and a benzthiazolyl group),

a silyl group (preferably having 3 to 40 carbon atoms, more preferably 3 to 30 carbon atoms, and particularly preferably 3 to 24 carbon atoms, exemplified by a trimethylsilyl group and a triphenylsilyl group),

a halogen atom (for example, a fluorine atom, a chlorine atom, a bromine atom, and an iodine atom),

a hydroxy group, a mercapto group, a cyano group, a nitro group, a hydroxamic group, a sulfino group, a hydrazino group, an imino group, an azo group, and the like can be used.

These substituents may be further substituted by any of these substituents. In a case where there are two or more substituents, these may be the same or different. If possible, the substituents may combine to form a ring.

Examples of the group in which the above substituent is further substituted by the above substituent include an R_{B}—(O—R_{A})ₙₐ- group in which an alkoxy group is substituted by an alkyl group. Here, in the formula, R_{A} represents an alkylene group having 1 to 5 carbon atoms, R_{B} represents an alkyl group having 1 to 5 carbon atoms, and na represents an integer of 1 to 10 (preferably 1 to 5, and more preferably 1 to 3).

Among these, as the monovalent substituent represented by L₁ or L₂, an alkyl group, an alkenyl group, an alkoxy group, and a group in which the above group is further substituted by the above group (for example, the above-described R_{B}—(O—R_{A})ₙₐ- group) are preferable, and an alkyl group, an alkoxy group, and a group in which the above group is further substituted by the above group (for example, the above-described R_{B}—(O—R_{A})ₙₐ- group) are more preferable.

Examples of the divalent linking group represented by L₁ or L₂ include —O—, —S—, —CO—, —COO—, —OCO—, —O—CO—O—, —CO—NR_{N}—, —O—CO—NR_{N}—, —NR_{N}—CO—NR_{N}—, —SO₂—, —SO—, an alkylene group, a cycloalkylene group, an alkenylene group, and a group obtained by combining two or more of these groups.

Among them, groups in which an alkylene group is combined with one or more groups selected from the group consisting of —O—, —COO—, —OCO— and —O—CO—O— are preferable.

Here, R_{N} represents a hydrogen atom or an alkyl group. In a case where there are plural R_{N}'s, the plural R_{N}'s may be the same or different.

From the viewpoint of a further improvement in the solubility of the specific dichroic dye compound, the number of atoms of the main chain of at least one of L₁ or L₂ is preferably 3 or more, more preferably 5 or more, even more preferably 7 or more, and particularly preferably l0 or more. The upper limit value of the number of atoms of the main chain is preferably 20 or less, and more preferably 12 or less.

From the viewpoint of a further improvement in the alignment degree of the light absorption anisotropic film, the number of atoms of the main chain of at least one of L₁ or L₂ is preferably 1 to 5.

Here, in a case where A is present in Formula (1), the “main chain” in L₁ refers to a portion necessary for directly connecting an “0” atom connecting to L₁ and “A”, and the “number of atoms of the main chain” refers to the number of atoms constituting the above portion. Similarly, in a case where B is present in Formula (1), the “main chain” in L₂ refers to a portion necessary for directly connecting an “0” atom connecting to L₂ and “B”, and the “number of atoms of the main chain” refers to the number of atoms constituting the above portion. The “number of atoms of the main chain” does not include the number of atoms of a branched chain to be described later.

In addition, in a case where A is not present, the “number of atoms of the main chain” in L₁ refers to the number of atoms of L₁ not containing a branched chain. In a case where B is not present, the “number of atoms of the main chain” in L₂ refers to the number of atoms of L₂ not containing a branched chain.

Specifically, in Formula (D1), the number of atoms of the main chain of L₁ is 5 (the number of atoms in the dotted line frame on the left side of Formula (D1)), and the number of atoms of the main chain of L₂ is 5 (the number of atoms in the dotted line frame on the right side of Formula (D1)). In addition, in Formula (D10), the number of atoms of the main chain of L₁ is 7 (the number of atoms in the dotted line frame on the left side of Formula (D10)), and the number of atoms of the main chain of L₂ is 5 (the number of atoms in the dotted line frame on the right side of Formula (D10)).

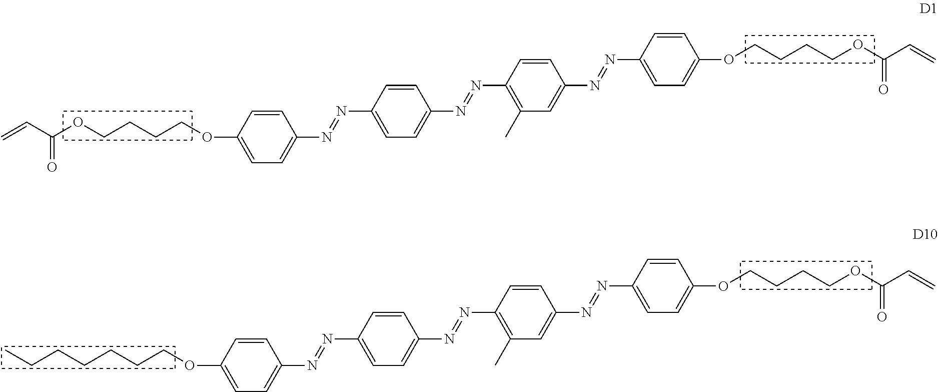

L₁ and L₂ may have a branched chain.

Here, in a case where A is present in Formula (1), the “branched chain” in L₁ refers to a portion other than the portion necessary for directly connecting an “O” atom connecting to L₁ and “A” in Formula (1). Similarly, in a case where B is present in Formula (1), the “branched chain” in L₂ refers to a portion other than the portion necessary for directly connecting an “O” atom connecting to L₂ and “B” in Formula (1).

In a case where A is not present in Formula (1), the “branched chain” in L₁ refers to a portion other than the longest atomic chain (that is, main chain) extending from the “O” atom connecting to L₁ in Formula (1). Similarly, in a case where B is not present in Formula (1), the “branched chain” in L₂ refers to a portion other than the longest atomic chain (that is, main chain) extending from the “O” atom connecting to L₂ in Formula (1).

The number of atoms of the branched chain is preferably 3 or less. In a case where the number of atoms of the branched chain is 3 or less, there is an advantage in that the alignment degree of the light absorption anisotropic film is further improved. The number of atoms of the branched chain does not include the number of hydrogen atoms.

In Formula (1), An represents a (n1+2)-valent (for example, trivalent in a case where n1 is 1) aromatic hydrocarbon group or heterocyclic group, Ar₂ represents a (n2+2)-valent (for example, trivalent in a case where n2 is 1) aromatic hydrocarbon group or heterocyclic group, and Ar₃ represents a (n3+2) -valent (for example, trivalent in a case where n3 is 1) aromatic hydrocarbon group or heterocyclic group. Here, each of Ar₁ to Ar₃ can be said to be a divalent aromatic hydrocarbon group or divalent heterocyclic group substituted by n1 to n3 substituents (R₁ to R₃ to be described later).

The divalent aromatic hydrocarbon group represented by any one of Ar₁, Ar₂, or Ar₃ may be monocyclic or may have a condensed ring structure of two or more rings. The number of rings of the divalent aromatic hydrocarbon group is preferably 1 to 4, more preferably 1 to 2, and even more preferably 1 (that is, a phenylene group) from the viewpoint of a further improvement in solubility.

Specific examples of the divalent aromatic hydrocarbon group include a phenylene group, an azulene-diyl group, a naphthylene group, a fluorene-diyl group, an anthracene-diyl group, and a tetracene-diyl group. From the viewpoint of a further improvement in solubility, a phenylene group and a n.aphthylene group are preferable, and a phenylene group is more preferable.

The divalent heterocyclic group may be either aromatic or non-aromatic, but from the viewpoint of a further improvement in alignment degree, it is preferably a divalent aromatic heterocyclic group.

The divalent aromatic heterocyclic group may be monocyclic or may have a condensed ring structure of two or more rings. Examples of the atom other than the carbon atom constituting the aromatic heterocyclic group include a nitrogen atom, a sulfur atom, and an oxygen atom. In a case where the aromatic heterocyclic group has a plurality of ring-constituting atoms other than the carbon atom, these may be the same or different.

Specific examples of the aromatic heterocyclic group include a pyridylene group (pyridine-diyl group), a thienylene (thiophene-diyl group), a quinolylene group (quinoline-diyl group), an isoquinolylenc group (isoquinoline-diyl group), a thiazole-diyl group, a benzothiadiazole-diyl group, a phthalimido-diyl group, a thienothiazole-diyl group (in the invention, referred to as “thienothiazole group”), a thienothiophene-diyl group, and a thienooxazole-diyl group.

Among these, as the divalent aromatic heterocyclic group, a monocyclic group or a group having a bicyclic condensed ring structure represented by the following structural formula can be preferably used. In the following structural formulae, “*” represents a bonding position to an azo group or an oxygen atom in General Formula (1).

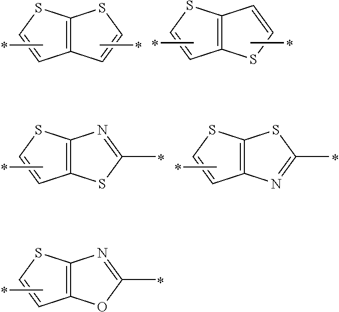

In Formula (1), Ar₁ to Ar₃ are preferably divalent aromatic hydrocarbon groups, and preferably phenylene groups.

Here, in a case where Ar₁ is a phenylene group, the oxygen atom and the azo group bonded to Ar₁ are preferably located in the meta- or para-position, and preferably located in the para-position. Accordingly, the alignment degree of the light absorption anisotropic film is further improved. From a similar viewpoint, in a case where Ar₂ is a phenylene group, the two azo groups bonded to Ar₂ are preferably located in the meta- or para-position, and preferably located in the para-position. Similarly, in a case where Ar₃ is a phenylene group, the oxygen atom and the azo group bonded to Ar₃ are preferably located in the meta- or para-position, and preferably located in the para-position.

In Formula (1), in a case where Ar₁, Ar₂, and Ar₃ have a condensed ring structure, all the rings constituting the condensed ring structure are preferably connected along the longitudinal direction of the structure represented by Formula (1). Accordingly, since it is possible to suppress the increase in the volume of molecule of the specific dichroic dye compound in a direction (lateral direction) intersecting with the longitudinal direction, the molecules have a good alignment property, and the alignment degree of the light absorption anisotropic film is further improved.

Here, the longitudinal direction of the structure represented by Formula (1) refers to an extending direction of the structure represented by Formula (1). Specifically, the longitudinal direction refers to an extending direction of bonds of the azo group and the ether bond (oxygen atom) bonded to Ar₁, Ar₂, and Ar₃.

Specific examples of the aspect in which all the rings constituting the condensed ring structure are connected along the longitudinal direction of the structure represented by Formula (1) include the following condensed ring structure represented by Formula (Ar-1). That is, in a case where Ar₁, Ar₂, and Ar₃ have a condensed ring structure, the condensed ring structure is preferably a condensed ring structure represented by Formula (A-1).

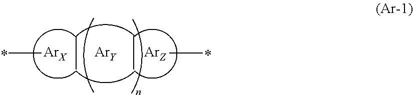

In Formula (Ar-1), Ar_{X}, Ar_{Y}, and Ar_{Z} each independently represent a benzene ring or a monocyclic heterocyclic ring. n represents an integer of 0 or more. * represents a bonding position to an azo group or an oxygen atom in General Formula (1).

A monocyclic aromatic heterocyclic ring is preferable as the monocyclic heterocyclic ring in Formula (Ar-1). Examples of the atom other than the carbon atom constituting the monocyclic aromatic heterocyclic group include a nitrogen atom, a sulfr atom, and an oxygen atom. Specific examples of the monocyclic aromatic heterocyclic ring include a pyridine ring, a thiophene ring, a thiazole ring, and an oxazole ring.

Ar_{X}, Ar_{Y}, and Ar_{Z} may have a substituent. Examples of the substituent include a monovalent substituent in R₁ to R₃ to be described later.

n represents an integer of 0 or more. The integer is preferably 0 to 2, more preferably 0 to 1, and even more preferably 0.

In Formula (1), R₁, R₂, and R₃ each independently represent a monovalent substituent.

The monovalent substituent represented by R₁, R₂, or R₃ is preferably a halogen atom, a cyano group, a hydroxy group, an alkyl group, an alkoxy group, a fluorinated alkyl group, —O—(C₂H₄O)m-R′, —O—(C₃H₆O)m-R′, an alkylthio group, an oxycarbonyl group, a thioalkyl group, an acyloxy group, an acylamino group, an alkoxycarbonylamino group, a sulfonylamino group, a sullamoyl group, a carbamoyl group, a sulfinyl group, or a ureido group. Here, R′ represents a hydrogen atom, a methyl group, or an ethyl group, and m represents an integer of 1 to 6. These substituents may be further substituted by any of these substituents.

Among these, a fluorine atom, a chlorine atom, a methyl group, an ethyl group, a propyl group, a methoxy group, an ethoxy group, a propoxy group, a hydroxy group, a trifluoromethyl group, —O—(C₂H₄O)m-R, or —O—(C₃H₆O)m-R′ is preferable, and a trifluoromethyl group, a methoxy group, a hydroxy group, —O—(C₂H₄O)m-R′, or —O—(C₃H₆O)m-R′ is more preferable as the monovalent substituent represented by R₁, R₂, or R₃ from the viewpoint of a further improvement in the solubility of the specific dichroic dye compound.

In the monovalent substituent represented by R₂, or R_{3,} the number of atoms of the main chain is preferably 1 to 15, and more preferably 1 to 12 from the viewpoint of a balance between the solubility of the specific dichroic dye compound and the alignment property of the light absorption anisotropic film. Here, in the monovalent substituent represented by R₁, R₂, or R₃, the “number of atoms of the main chain” refers to the number of atoms of R₁, R₂, or R₃ containing no branched chain. The “branched chain” refers to a portion other than the longest atomic chain (that is, main chain) extending from any one of Ar₁, Ar₂, or Ar₃ in Formula (1).

In a case where Formula (1) has at least one substituent selected from R₁, R₂ or R₃, it is preferable to satisfy at least one condition selected from the following condition (R1), (R2), or (R₃). Accordingly, the solubility of the specific dichroic dye compound is further improved.

Condition (R1): In Ar₁, at least one R₁ and an azo group are positioned next to each other.

Condition (R2): In Ar₂, at least one R₂ and at least one azo group are positioned next to each other.

Condition (R3): In Ar₃, at least one R₃ and an azo group are positioned next to each other.

Specific examples of the condition (R1) include an aspect in which in a case where Ar₁ is a phenylene group, R₁ is located in the ortho-position relative to the azo group bonded to Ar₁. Specific examples of the condition (R2) include an aspect in which in a case where Ar₂ is a phenylene group, R₂ is located in the ortho-position relative to at least one azo group. Specific examples of the condition (R₃) include an aspect which in a case where Ar₃ is a phenylene group, R₃ is located in the ortho-position relative to the azo group bonded to Ar₃.

In Formula (1), k represents an integer of 1 to 4. Here, k is preferably 2 or more from the viewpoint of ensuring excellent solubility and excellent light resistance. From the viewpoint of more excellent solubility of the specific dichroic dye compound, k is preferably 1.

In Formula (1), n1, n2 and n3 each independently represent an integer of 0 to 4, and is preferably 0 to 3.

Here, in a case where k is 1, n1+n2+n3 is not less than 0. That is, in a case where Formula (1) has a bisazo structure, sufficient solubility can be obtained regardless of the presence or absence of the substituent (R₁ to R₃ of Formula (1)), but from the viewpoint of a further improvement in solubility, Formula (1) preferably has a substituent.

In a case where k is 1, n1+n2+n3 is preferably 0 to 9, more preferably 1 to 9, and even more preferably 1 to 5.

In a case where k is not less than 2, n1+n2+n3 is not less than 1. That is, in a case where Formula (1) has a trisazo structure, a tetrakisazo structure, or a pentakisazo structure, Formula (1) has at least one substituent (R₁ to R₃ of Formula (1)).

In a case where k is not less than 2, n1+n2+n3 is preferably 1 to 9, and more preferably 1 to 5.

Specific examples of the specific dichroic dye compound are shown as follows, but the invention is not limited thereto. In the following specific examples, n represents an integer of 1 to 10.

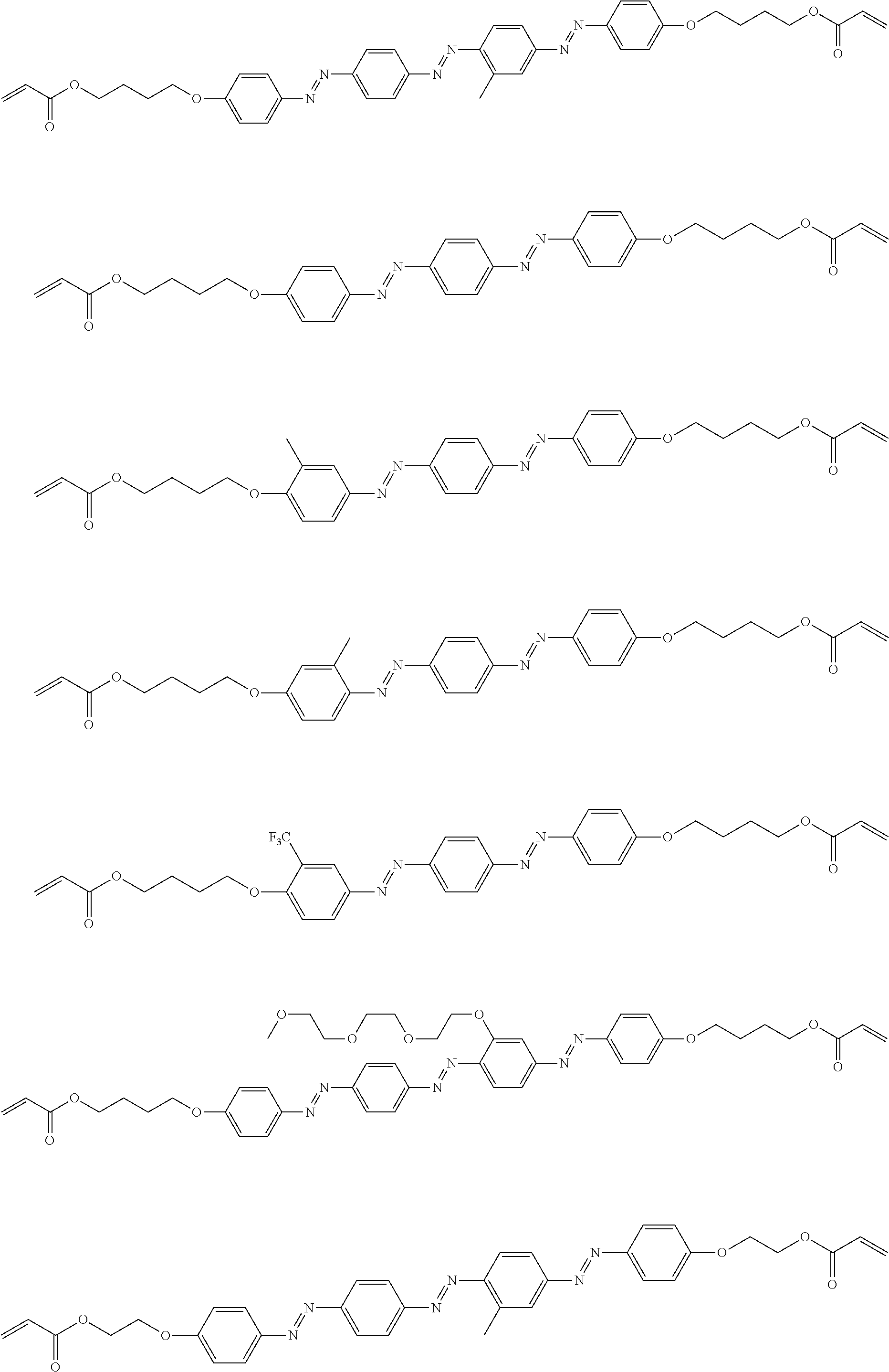

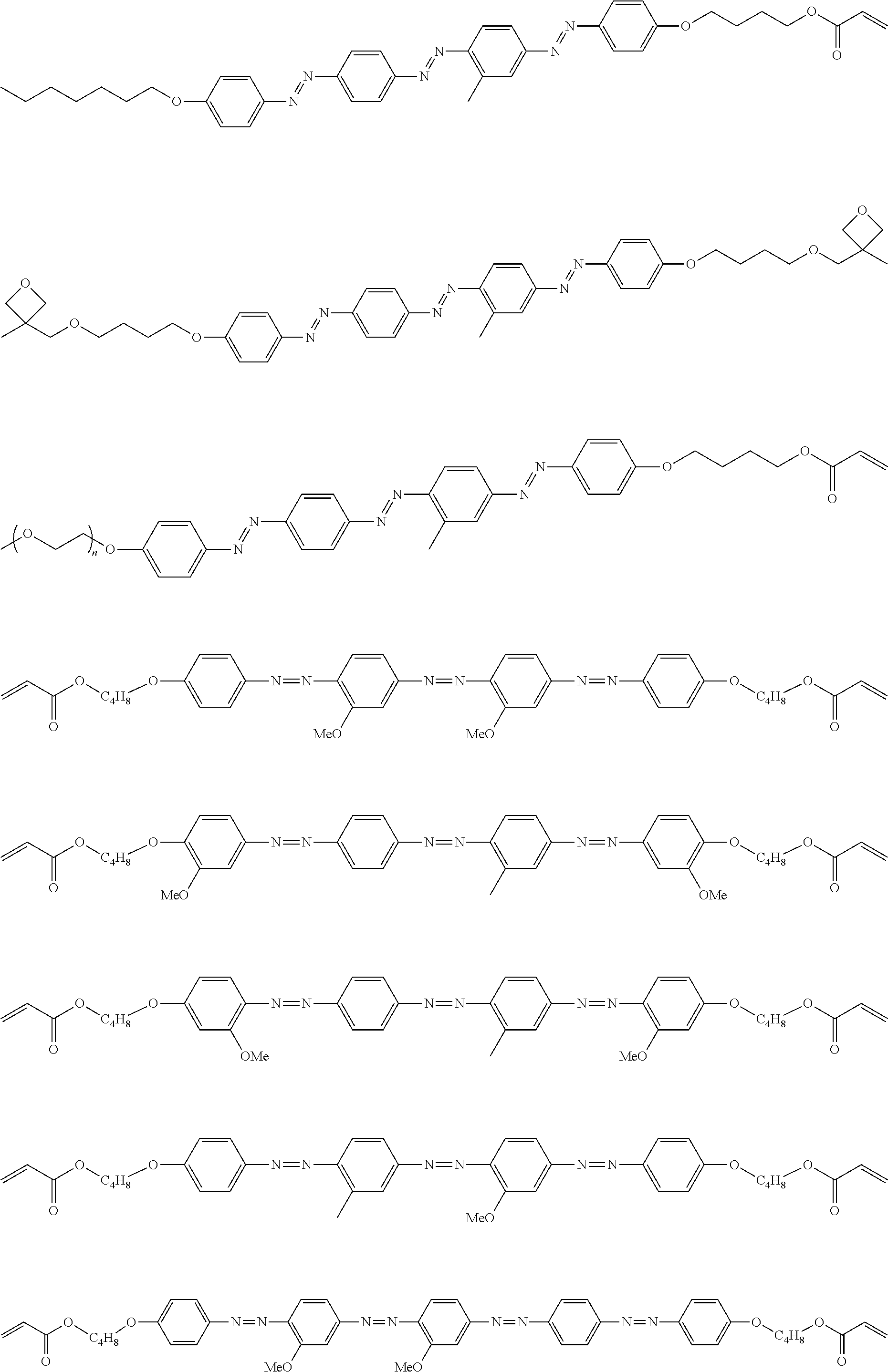

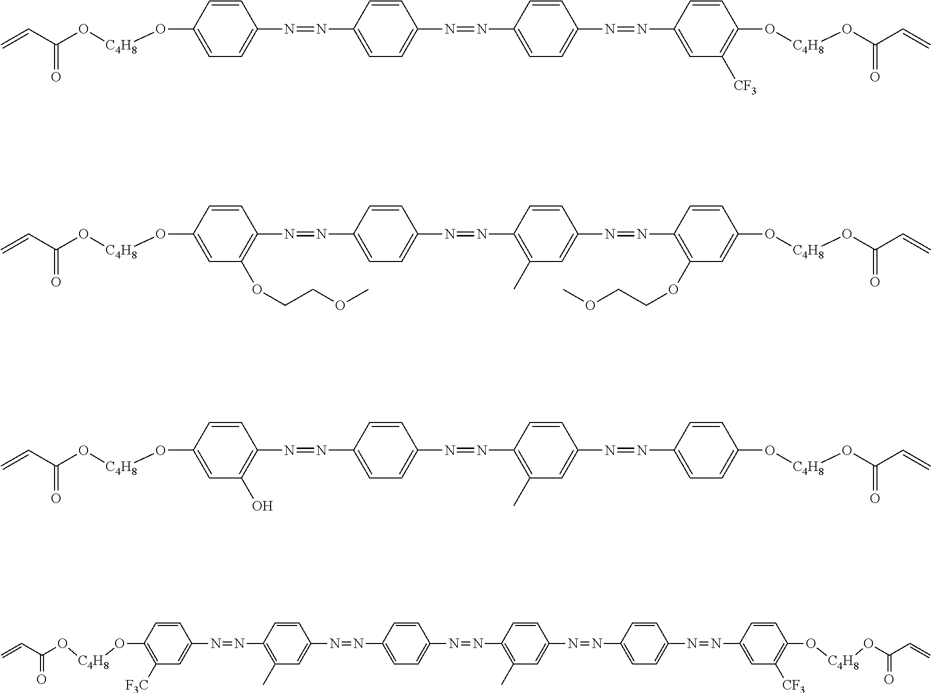

In the invention, the dichroic dye compound means a dye in which the absorbance varies depending on the direction.

The specific dichroic dye compound may or may not exhibit liquid crystallinity.

In a case where the specific dichroic dye compound exhibits liquid crystallinity, it may be either nematic or smectic. The temperature range in which a liquid crystalline phase is shown is preferably room temperature (approximately 20° C. to 28° C.) to 300° C., and more preferably 50° C. to 200° C. from the viewpoint of handleability and manufacturing suitability.

The coloring composition according to the embodiment of the invention may contain one or two or more kinds of specific dichroic dye compounds.

<Liquid Crystalline Compound>

The coloring composition according to the embodiment of the invention preferably contains a liquid crystalline compound. In a case where the liquid crystalline compound is contained, it is possible to align the specific dichroic dye compound at a high alignment degree while suppressing the precipitation of the specific dichroic dye compound.

The liquid crystalline compound is not dichroic.

Any one of a low-molecular-weight liquid crystalline compound or a high-molecular-weight liquid crystalline compound can be used as the liquid crystalline compound. Here, the “low-molecular-weight liquid crystalline compound” refers to a liquid crystalline compound having no repeating unit in the chemical structure. The “high-molecular-weight liquid crystalline compound” refers to a liquid crystalline compound having a repeating unit in the chemical structure.

Examples of the low-molecular-weight liquid crystalline compound include those described in JP2013-228706A.

Examples of the high-molecular-weight liquid crystalline compound include thermotropic liquid crystalline polymers described in JP2011-237513A. In addition, the high-molecular-weight liquid crystalline compound may have a crosslinkable group (for example, an acryloyl group and a methacryloyl group) at a terminal.

The liquid crystalline compounds may be used alone or in combination of two or more kinds thereof.

In a case where the liquid crystalline compound is contained, the content of the liquid crystalline compound is preferably 25 to 2,000 parts by mass, more preferably 33 to 1,000 parts by mass, and even more preferably 50 to 500 parts by mass with respect to 100 parts by mass of the content of the specific dichroic dye compound in the coloring composition. In a case where the content of the liquid crystalline compound is within the above range, the alignment degree of the light absorption anisotropic film is further improved.

<Solvent>

The coloring composition according to the embodiment of the invention preferably contains a solvent from the viewpoint of workability or the like.

Examples of the solvent include organic solvents such as ketones (for example, acetone, 2-butanone, methyl isobutyl ketone, cyclopentanone, and cyclohexanone), ethers (for example, dioxane, tetrahydrofuran, 2-methyltetrahydrofuran, cyclopentyl methyl ether, and tetrahydropyran), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane, dichloroethane, dichlorobenzene, and chlorotoluene), esters (for example, methyl acetate, ethyl acetate, butyl acetate, and ethyl lactate), alcohols (far example, ethanol, isopropanol, butanol, cyclohexanol, osopentyl alcohol, neopentyl alcohol, diacetone alcohol, and benzyl alcohol), cellosolves (for example, methyl cellosolve, ethyl cellosolve, and 1,2-dimethoxyethane), cellosolve acetates, sulfoxides (for example, dimethyl sulfoxide), amides (for example, dimethylfonnamide and dimethylacetamide), and heterocyclic compounds (for example, pyridine), and water. These solvents may be used alone or in combination of two or more kinds thereof.

Among these solvents, ketones (particularly, cyclopentanone and cyclohexanone) and ethers (particularly, tetrahydrofuran, cyclopentyl methyl ether, and tetrahydropyran) are preferable from the viewpoint of utilizing the effect of excellent solubility of the invention.

In a case where the coloring composition according to the embodiment of the invention contains a solvent, the content of the solvent is preferably 80 to 99 mass %, more preferably 83 to 98 mass %, and even more preferably 85 to 96 mass % with respect to the total mass of the coloring composition.

<Interface Improver>

The coloring composition according to the embodiment of the invention preferably contains an interface improver. Due to the interface improver contained, the smoothness of the coating surface is improved and the aligmnent degree is improved. In addition, cissing and unevenness are suppressed, and thus an improvement in the in-plane uniformity is anticipated.

As the interface improver, a material making the liquid crystalline compound horizontal on the coating surface side is preferable, and compounds (horizontal aligmnent agents) described in paragraphs [0253] to [0293] of JP2011-237513A can be used.

In a case where the coloring composition according to the embodiment of the invention contains an interface improver, the content of the interface improver is preferably 0.1 to 500 parts by mass, and more preferably 1 to 100 parts by mass with respect to 100 parts by mass of the specific dichroic dye compound in the coloring composition.

<Polymerization Initiator>

The coloring composition used in the invention preferably contains a polymerization initiator.

The polymerization initiator is not particularly limited, and a photosensitive compound, that is, a photopolymerization initiator is preferable.

As the photopolymerization initiator, various kinds of compounds can be used with no particular limitation. Examples of the photopolymerization initiator include α-carbonyl compounds (the specifications of U.S. Pat. No. 2,367,661A and U.S. Pat. No. 2,367,670A), acyloin ethers (the specification of U.S. Pat. No. 2,448,828A), aromatic acyloin compounds substituted by α-hydrocarbon (the specification of U.S. Pat. No. 2,722,512A), polynuclear quinone compounds (the specifications of U.S. Pat. No. 3,046,127A and U.S. Pat. No. 2,951,758A), combinations of triarylimidazole dimers and p-aminophenyl ketones (the specification of U.S. Pat. No. 3,549,367A), acridine and phenazine compounds (the specifications of JP1985-105667A (JP-S60-105667A) and U.S. Pat. No. 4,239,850A), oxadiazole compounds (the specification of U.S. Pat. No. 4,212,970A), and acylphosphine oxide compounds (JP1988-40799B (JP-S63-407998), JP1993-29234B (JP-H5-29234B), JP1998-95788B (JP-H10-95788B), and JP1998-29997B (JP-H10-29997B)).

A commercially available product can also be used as the photopolymerization initiator, and examples thereof include IRGACURE 184, IRGACURE 907, IRGACURE 369, IRGACURE 651, IRGACURE 819, and IRGACURE OXE-01 manufactured by BASF SE.

In a case where the coloring composition according to the embodiment of the invention contains a polymerization initiator, the content of the polymerization initiator is preferably 0.1 to 500 parts by mass, and more preferably 1 to 100 parts by mass with respect to 100 parts by mass of the specific dichroic dye compound in the coloring composition. In a case where the content of the polymerization initiator is 0.1 parts by mass or more, the curability of the light absorption anisotropic film is improved, and in a case where the content of the polymerization initiator is 500 parts by mass or less, the alignment of the light absorption anisotropic film is improved.

<Other Dichroic Dye Compounds>

The coloring composition according to the embodiment of the invention may further contain one or more kinds of dichroic dye compounds (hereinafter, also referred to as “other dichroic dye compounds”) other than the specific dichroic dye compound. In a case where a polarizer having good polarizing performance in the whole visible region is produced, a dichroic dye compound having a maximum absorption wavelength within a wavelength range of 500 to 700 nm is preferable.

Examples of other dichroic dye compounds include dichroic dyes described in paragraphs [0067] to [0071] of JP2013-228706A, paragraphs [0008] to [0026] of JP2013-227532A, paragraphs [0008] to [0015] of JP2013-209367A, paragraphs [0045] to [0060] of JP2013-148883A, paragraphs [0012] to [0029] of JP2013-109090A, paragraphs [0009] to [0017] of JP2013-101328A, paragraphs [0051] to [0065] of JP2013-037353A, paragraphs [0049] to [0073] of JP2012-063387A, paragraphs [0016] to [0018] of JP1999-305036A (JP-1111-305036A), paragraphs [0009] to [0011] of JP2001-133630A, and paragraphs [0030] to [0169] of JP2011-215337A, and dichroic dye polymers having thermotropic liquid crystallinity described in paragraphs [0035] to [0062] of JP2016-004055A.

In a case where the coloring composition according to the embodiment of the invention contains other dichroic dye compounds, the content of other dichroic dye compounds is preferably 20 to 500 parts by mass, and more preferably 30 to 300 parts by mass with respect to 100 parts by mass of the specific dichroic dye compound in the coloring composition.

[Light Absorption Anisotropic Film]

The light absorption anisotropic film according to the embodiment of the invention is formed using the above-described coloring composition.

Examples of the method of manufacturing the light absorption anisotropic film according to the embodiment of the invention include a method including, in order, a step of forming a coating film by applying the coloring composition to a base (hereinafter, also referred to as “coating film forming step”) and a step of aligning the specific dichroic dye compound contained in the coating film (hereinafter, also referred to as “alignment step”).

Hereinafter, the method of manufacturing the light absorption anisotropic film will be described for each step.

<Coating Film Forming Step>

The coating film forming step is a step of forming a coating film by applying the coloring composition to a base.

By using a coloring composition containing the above-described solvent, or a liquid material such as a molten liquid obtained by heating the coloring composition, the coloring composition is easily applied to the base.

Examples of the method of applying the coloring composition include known methods such as a roll coating method, a gravure printing method, a spin coating method, a wire bar coating method, an extrusion coating method, a direct gravure coating method, a reverse gravure coating method, a die coating method, a spray method, and an ink jet method.

In this aspect, an example has been given in which the coloring composition is applied to the base, but the invention is not limited thereto. For example, the coloring composition may be applied to an alignment film provided on the base. Details of the alignment film will be described later.

<Alignment Step>

The alignment step is a step of aligning the specific dichroic dye compound contained in the coating film. Thus, a light absorption anisotropic film is obtained. In the following example, a case where the specific dichroic dye compound has liquid crystallinity will be described as an example. In a case where the coloring composition contains the above-described liquid crystalline compound, it is aligned in the same manner as the specific dichroic dye compound.

The alignment step may have a drying treatment. Through the drying treatment, a component such as a solvent can be removed from the coating film. The drying treatment may be performed by a method of leaving the coating film for a predetermined time at room temperature (for example, natural drying), or a heating and/or air blowing method.

Here, the specific dichroic dye compound contained in the coloring composition may be aligned by the above-described coating film forming step or drying treatment. For example, in an aspect in which the coloring composition is prepared as a coating liquid containing a solvent, the coating film is dried to remove the solvent from the coating film, and thus a coating film having light absorption anisotropy (that is, light absorption anisotropic film) is obtained.

A heating treatment to be described later may not be performed in a case where the drying treatment is performed at a temperature of not lower than a temperature at which the specific dichroic dye compound contained in the coating film transits to a liquid crystalline phase.

The temperature at which the specific dichroic dye compound contained in the coating film transits to a liquid crystalline phase is preferably 10° C. to 250° C., and more preferably 25° C. to 190° C. in view of manufacturing suitability or the like. The transition temperature is preferably 10° C. or higher since a cooling treatment or the like for lowering the temperature to a temperature range in which the liquid crystalline phase is exhibited is not required. In addition, the transition temperature is preferably 250° C. or lower since even in an isotropic liquid state with a temperature higher than the temperature range in which the liquid crystalline phase is exhibited, high temperature is not required, and thus the waste of thermal energy and the deformation, degeneration, or the like of the substrate can be reduced.

The alignment step preferably has a heating treatment. Accordingly, the specific dichroic dye compound contained in the coating film can be aligned, and thus the coating film after the heating treatment can be preferably used as a light absorption anisotropic film.

The heating treatment is preferably performed at 10° C. to 250° C., and more preferably at 25° C. to 190° C. in view of manufacturing suitability or the like. The heating time is preferably 1 to 300 seconds, and more preferably 1 to 60 seconds.

The alignment step may have a cooling treatment to be performed after the heating treatment. The cooling treatment is a treatment for cooling the coating film after the heating to about room temperature (20° C. to 25° C.). Accordingly, the alignment of the specific dichroic dye compound contained in the coating film can be fixed. The cooling means is not particularly limited, and the cooling can be performed by a known method.

By the above steps, a light absorption anisotropic film can be obtained.

In this aspect, examples of the method of aligning the specific dichroic dye compound contained in the coating film include the drying treatment and the heating treatment, but are not limited thereto, and a known alignment treatment can be used.

<Other Steps>

The method of manufacturing a light absorption anisotropic film may have a step of curing the light absorption anisotropic film (hereinafter, also referred to as “curing step”) after the alignment step. Accordingly, a light absorption anisotropic film having more excellent durability is obtained.

The curing step is perthrmed by, for example, heating and/or light irradiation (exposure). Among these, light irradiation is preferably performed to conduct the curing step.

As the light source used for curing, various light sources can be used such as infrared rays, visible light, and ultraviolet rays, and ultraviolet rays are preferable. In the curing, ultraviolet rays may be applied during heating, or may be applied via a filter which transmits only a component with a specific wavelength.

In a case where the exposure is perthrmed during heating, although depending on the temperature at which the specific dichroic dye compound contained in the light absorption anisotropic film transits to a liquid crystalline phase, the heating temperature during the exposure is preferably 25′C to 140° C.

In addition, the exposure may be performed under a nitrogen atmosphere. In a case where the light absorption anisotropic film is cured by radical polymerization, inhibition of the polymerization by oxygen is reduced, and thus the exposure is preferably performed under a nitrogen atmosphere.

The film thickness of the light absorption anisotropic film is preferably 0.1 to 5.0 μm, and more preferably 0.3 to 1.5 μm. Although depending on the concentration of the dichroic dye compound in the coloring composition, a light absorption anisotropic film having an excellent absorbance is obtained in a case where the film thickness is 0.1 μm or greater, and a light absorption anisotropic film having an excellent transmittance is obtained in a case where the film thickness is 5.0 μm or less.

[Laminate]

A laminate according to the embodiment of the invention has a base and the light absorption anisotropic film formed on the base. The laminate according to the embodiment of the invention may further have a λ/4 plate formed on the light absorption anisotropic film and an oxygen blocking layer formed on the light absorption anisotropic film. In addition, the laminate according to the embodiment of the invention may have both the λ/4 plate and the oxygen blocking layer.

In addition, the laminate according to the embodiment of the invention preferably has an alignment film between the base and the light absorption anisotropic film.

Hereinafter, the constituent layers of the laminate will be described.

<Base>

The base can be selected in accordance with usage of the light absorption anisotropic film, and examples thereof include glass and a polymer film. The light transmittance of the base is preferably 80% or greater.

The base may also serve as a substrate of an image display device, or as a laminate including a functional layer as a liquid crystal display device. For example, in a liquid crystal display device to be described later, the base may also serve as a glass substrate of a liquid crystal cell, or as a laminate including a color filter or a transparent electrode.

In a case where a polymer film is used as the base, an optically isotropic polymer film is preferably used. As specific examples and preferable aspects of the polymer, those described in a paragraph [0013] of JP2002-022942A can be applied. In addition, even a conventionally known polymer such as polycarbonate or polysuifone in which birefringence is likely to be developed can also be used by reducing the developability through molecular modification described in WO00/26705A.

<Light Absorption Anisotropic Film>

Since the light absorption anisotropic film is as described above, the description thereof will be omitted.

<λ/4 Plate>

The “λ/4 plate” is a plate having a λ/4 function, and is specifically, a plate having a fimcfion of converting linearly polarized light with a specific wavelength into circularly polarized light (or converting circularly polarized light into linearly polarized light).

Specific examples of the λ/4 plate include US2015/0277006A.

For example, in an aspect in which the λ/4 plate has a single layer structure, specific examples of the plate include a retardation film in which an optically anisotropic layer having a λ/4 function is provided on a stretched polymer film or a support. In an aspect in which the λ/4 plate has a multilayered structure, specific examples of the plate include a broadband λ/4 plate having a laminate of a λ/4 plate and a λ/4 plate.

The λ/4 plate and the light absorption anisotropic film may be provided in contact with each other, or another layer may be provided between the λ/4 plate and the light absorption anisotropic film. Examples of the layer include a pressure sensitive layer and an adhesive layer.

<Oxygen Blocking Layer>

The laminate according to the embodiment of the invention may have an oxygen blocking layer to improve heat resistance.

The “oxygen blocking layer” is an oxygen blocking film having an oxygen blocking function, and specific examples thereof include a layer containing an organic compound such as polyvinyl alcohol, polyethylene vinyl alcohol, polyvinyl ether, polyvinyl pyrrolidone, polyacrylamide, polyacrylic acid, cellulose ether, polyimide, polyimide, styrene/maleic acid copolymer, gelatin, vinylidene chloride, or cellulose nanofiber.

In this specification, the oxygen blocking function is not limited to a state in which oxygen is not passed at all, and includes a state in which oxygen is slightly passed depending on the target performance.

The examples further include a thin layer (metal compound thin layer) made of a metal compound. As a method of forming the metal compound thin layer, any method can be used as long as a target thin layer can be formed. For example, a sputtering method, a vacuum vapor deposition method, an ion plating method, or a plasma chemical vapor deposition (CND) method is suitable, and specifically, a forming method described in JP3400324B, JP2002-322561A, or JP2002-361774A can be employed.

The component contained in the metal compound thin layer is not particularly limited as long as it can exhibit an oxygen blocking function. For example, an oxide, nitride or oxynitride including one or more kinds of metals selected from Si, Al, In, Sn, Zn, Ti, Cu, Ce, and Ta can be used. Among these, an oxide, nitride, or oxynitride of a metal selected from Si, Al, In, Sn, Zn and Ti is preferable, and an oxide, nitride, or oxynitride of a metal selected from Si, Al, Sn, and Ti is particularly preferable. These may contain other elements as a subcomponent.

As described in U.S. Pat. No. 6,413,645B, JP2 15-226995A, JP2013-202971A, JP2003-335880A, JP1978-012953B (JP-S53-012953B), and JP1983-217344A (JP-S58-217344A), the oxygen blocking layer may have a form in which the layer containing an organic material and the metal compound thin layer are laminated. In addition, as described in WO2011/118 36A, JP2013-248832A, and JP3855004B, the oxygen blocking layer may a layer in which an organic compound and an inorganic compound are hybridized.

In a case where the laminate according to the embodiment of the invention has the above-described λ/4 plate and the λ/4 plate is a retardation film in which an optically anisotropic layer having a λ/4 function is provided on a support, the oxygen blocking layer may also serve as an alignment film of the optically anisotropic layer having a λ/4 function. In such a case, the oxygen blocking layer preferably contains polyvinyl alcohol, polyamide, or polyimide.

Regarding the film thickness of the oxygen blocking layer, the layer containing an organic compound preferably has a thickness of 0.1 to 10 μm, and more preferably 0.5 to 5.5 μm. The metal compound thin layer preferably has a thickness of 5 to 500 μm, and more preferably 10 to 200 μm.

In a case where high heat is applied to the laminate and the laminate has an oxygen blocking layer, the oxygen blocking layer exerts an effect. Accordingly, the oxygen blocking layer may be removed after the application of high heat, and then another layer may be formed.

<Alignment Film>

The laminate according to the embodiment of the invention may have an alignment film between the base and the light absorption anisotropic film.

As the alignment film, any layer may be used as long as it allows the specific dichroic dye compound contained in the coloring composition according to the embodiment of the invention on the alignment film to have a desired alignment state.

The alignment film can be provided by means of a rubbing treatment on the film surface with an organic compound (preferably a polymer), oblique vapor deposition of an inorganic compound, forming a layer having microgrooves, or accumulation of an organic compound (for example, ω-tricosanoic acid, dioctadecylmethylammonium chloride or methyl stearate) by the Langmuir-Blodgett method (LB film). Furthermore, there have been known alignment films having an aligning function imparted thereto by applying an electrical field, applying a magnetic field, or light irradiation. In the invention, among these, an alignment film formed by a rubbing treatment is preferable in view of easy control of a pretilt angle of the alignment film, and a photo-alignment film formed by light irradiation is also preferable in view of alignment uniformity.

(Rubbed Alignment Film)

The polymer material used for an alignment film formed by a rubbing treatment is described in many literatures, and many commercially available products are available. In the invention, polyvinyl alcohol or polyimide, or derivatives thereof can be preferably used. Regarding the alignment film, the description in the 24th line on page 43 to 8th line on page 49 in WO01/88574M can be referred to. The thickness of the alignment film is preferably 0.01 to 10 μm, and more preferably 0.01 to 1 μm.

(Photo-Alignment Film)

The photo-alignment material used for an alignment film formed by light irradiation is described in many literatures. In the invention, preferable examples thereof include azo compounds described in JP2006-285197A, JP2007-076839A, JP2007-138138A, JP2007-094071A, JP2007-121721 A, JP2007-140465A, JP2007-156439A, JP2007-133184A, JP2009-109831A, JP3883848B, and JP4151746B, aromatic ester compounds described in JP2002-229039A, maleimide and/or alkenyl-substituted nadimide compounds having photo-alignment units described in JP2002-265541A and JP2002-317013A, photocrosslinkable silane derivatives described in JP4205195B and JP4205198B, and photocrosslinkable polyimides, polyamides, and esters described in JP2003-520878A, JP2004-529220A, and JP4162850B. Azo compounds, photocrosslinkable polyimides, polyamides, and esters are more preferable.

To a photo-alignment film formed from the above-described material, linearly polarized light or unpolarized light is applied to manufacture a photo-alignment film.

In this specification, the “linearly polarized light irradiation” and the “unpolarized light irradiation” are operations for causing a photoreaction to the photo-alignment material. The wavelength of the light used is not particularly limited as long as the wavelength varies depending on the photo-alignment material used and is a wavelength necessary for the photoreaction. The peak wavelength of the light used for light irradiation is preferably 200 nm to 700 nm, and ultraviolet light having a light peak wavelength of 400 nm or less is more preferable.

The light source used for light irradiation is a usually used light source, and examples thereof include lamps such as a tungsten lamp, a halogen lamp, a xenon lamp, a xenon flash lamp, a mercury lamp, a mercury/xenon lamp, and a carbon arc lamp, various lasers [for example, a semiconductor laser, a helium/neon laser, an argon ion laser, a helium/cadmium laser, and an YAG (yttrium/aluminum/garnet) laser], light emitting diodes, and cathode ray tubes.

As means for obtaining linearly polarized light, a method using a polarizing plate (for example, an iodine polarizing plate, a dichroic dye polarizing plate, or a wire grid polarizing plate), a method using a prism-based element (for example, a GLAN-THOMSON prism) or a reflective polarizer using a BREWSTER angle, or a method using light emitted from a polarized laser light source can be employed. Only light having a necessary wavelength may be selectively applied by using a filter, a wavelength conversion element, or the like.

In a case where linearly polarized light is used as light for irradiation, a method of irradiating the alignment film with light from an upper surface or a rear surface in a direction vertical or oblique to the alignment film surface is employed. Although the incidence angle of the light varies depending on the photo-alignment material, the incidence angle is preferably 0° to 90° (vertical), and preferably 40° to 90°.

In a case where unpolarized light is used, the alignment film is irradiated with unpolarized light from an oblique direction. The incidence angle of the light is preferably 10° to 80°, more preferably 20° to 60°, and even more preferably 30° to 50°.

The irradiation time is preferably 1 minute to 60 minutes, and more preferably 1 minute to 10 minutes.

In a case where patterning is required, a method of performing light irradiation using a photomask as many times as necessary for pattern formation, or a pattern writing method using laser beam scanning can be employed.

<Usage>

The laminate according to the embodiment of the invention can be used as a polarizing element (polarizing plate). For example, it can be used as a linearly polarizing plate or a circularly polarizing plate.

In a case where the laminate according to the embodiment of the invention has no optically anisotropic layer such as the λ/4 plate, the laminate can be used as a linearly polarizing plate. In a case where the laminate according to the embodiment of the invention has the λ/4 plate, the laminate can be used as a circularly polarizing plate.

[Image Display Device]

An image display device according to the embodiment of the invention has the above-described light absolution anisotropic film or the above-described laminate.

The display element used for the image display device according to the embodiment of the invention is not particularly limited, and examples thereof include a liquid crystal cell, an organic electroluminescence (hereinafter, abbreviated as “EL”), a display panel, and a plasma display panel.

Among these, a liquid crystal cell or an organic EL display panel is preferable, and a liquid crystal cell is more preferable. That is, as the image display device according to the embodiment of the invention, a liquid crystal display device using a liquid crystal cell as a display element, or an organic EL display device using an organic EL display panel as a display element is preferable, and a liquid crystal display device is more preferable.

<Liquid Crystal Display Device>

A liquid crystal display device as an example of the image display device according to the embodiment of the invention preferably has an aspect in which it has the above-described light absorption anisotropic film and a liquid crystal cell. More preferably, the liquid crystal display device has the above-described laminate (but including no λ/4 plate) and a liquid crystal cell.

In the invention, it is preferable that the light absorption anisotropic film (laminate) according to the embodiment of the invention be used as a polarizing element on the front side among light absorption anisotropic films (laminates) to be provided on both sides of a liquid crystal cell, and it is more preferable that the light absorption anisotropic film. (laminate) according to the embodiment of the invention be used as polarizing elements on the front side and the rear side.

Hereinafter, the liquid crystal cell of the liquid crystal display device will be described in detail.

(Liquid Crystal Cell)

The liquid crystal cell used for the liquid crystal display device is preferably a vertical alignment (VA) mode, an optical compensated bend (OCB) mode, an in-plane-switching (IPS) mode, or a twisted nematic (TN) mode, but is not limited thereto.

In a TN mode liquid crystal cell, with no application of a voltage, rod-like liquid crystalline molecules are substantially horizontally aligned, and twist-aligned by 60° to 120°. The TN mode liquid crystal cell is most frequently used as a color thin film transistor (TFT) liquid crystal display device, and is described in many literatures.

In a VA mode liquid crystal cell, rod-like liquid crystalline molecules are substantially vertically aligned with no application of a voltage. The VA mode liquid crystal cell includes (1) a narrowly-defined VA mode liquid crystal cell in which rod-like liquid crystalline molecules are substantially vertically aligned with no application of a voltage, and are substantially horizontally aligned with the application of a voltage (described in JP1990-176625A (JP-H2-176625A)), (2) a (MVA mode) liquid crystal cell in which the VA mode is made into multi-domains in order to expand the viewing angle (described in SID97, Digest of tech. Papers (proceedings) 28 (1997) 845), (3) an (n-ASM mode) liquid crystal cell in which rod-like liquid crystalline molecules are substantially vertically aligned with no application of a voltage, and are twisted in multi-domains with the application of a voltage (described in the proceedings 58 and 59 of Japanese Liquid Crystal Conference (1998)), and (4) a SURVIVAL mode liquid crystal cell (announced at LCD internal 98). In addition, the VA mode liquid crystal cell may be any one of a patterned vertical alignment (PVA) type, an optical alignment type, or a polymer-sustained alignment (PSA) type. Details of these modes are described in JP2006-215326A and JP2008-538819A.

In an IPS mode liquid crystal cell, rod-like liquid crystalline molecules are substantially horizontally aligned with respect to a substrate, and the liquid crystalline molecules respond in a planar manner with the application of an electric field parallel to a substrate surface. The IPS mode displays a black image in a state in which no electric field is applied thereto, and the absorption axes of a pair of upper and lower polarizing plates are perpendicular to each other. A method of improving the viewing angle by reducing light leakage caused when a black image is displayed in an oblique direction using an optical compensation sheet is disclosed by JP1998-054982A (JP-H10-054982A), JP1999-202323A (JP-H11-202323 A), JP1997-292522A (JP-H9-292522A), JP1999-133408A (JP-H11-133408A), JP1999-305217A (JP-H11-305217A), JP1998-307291A (JP-H10-307291A), and the like.

<Organic EL Display Device>

An organic EL display device as an example of the image display device according to the embodiment of the invention preferably has an aspect in which it has a light absorption anisotropic film, a λ/4 plate, and an organic EL display panel in this order from the visual recognition side.

More preferably, the organic EL display device has the above-described laminate having a λ/4 plate and an organic EL display panel in this order from the visual recognition side. In this case, the laminate has a base, an alignment film to be provided as necessary, a light absorption anisotropic film, and a λ/4 plate disposed in this order from the visual recognition side.

In addition, the organic EL display panel is a display panel configured using an organic EL element in which an organic light emitting layer (organic electroluminescence layer) is interposed between electrodes (between a cathode and an anode). The configuration of the organic EL display panel is not particularly limited, and a known configuration is employed. Examples

Hereinafter, the invention will be more specifically described based on examples. Materials, used amounts, ratios, treatment contents, treatment procedures, and the like shown in the following examples are able to be properly changed without departing from the gist of the invention. Therefore, the scope of the invention will not be restrictively interpreted by the following examples.

[Synthesis of Dichroic Dye Compound D1]

A dichroic dye compound D1 was synthesized as follows.

First, 4-hydroxyhutyl acrylate (20 g) and mesyl chloride (16.8 g, MsCl) were dissolved in ethyl acetate (90 mL). Then, while the resulting mixture was cooled in an ice bath, triethylamine (16.4 g, NEt₃) was added dropwise thereto. After that, stirring was perfomied at room temperature for 2 hours, and then 1N HCl was added for liquid separation. The obtained organic layer was distilled off under reduced pressure to obtain a compound X (30 g) having the following structure.

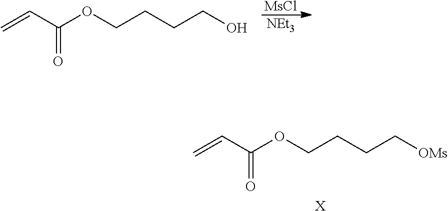

A dichroic dye compound D1 was synthesized according to the following route.

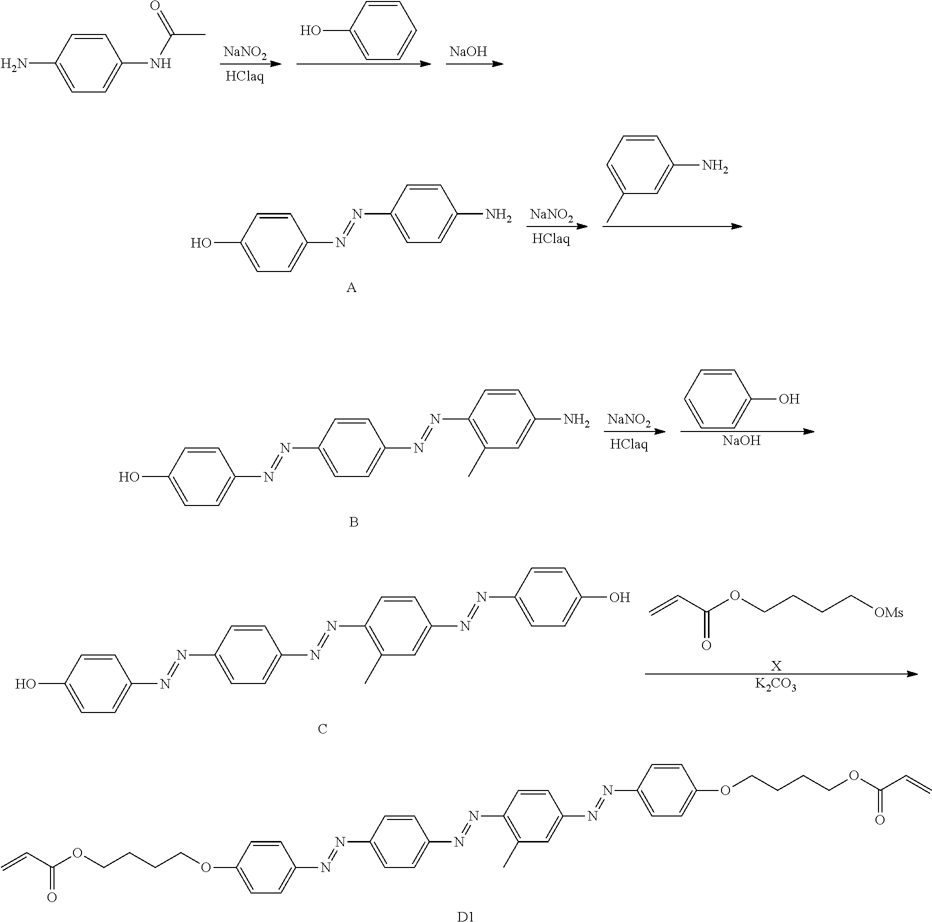

First, a compound A (10 g) was synthesized according to the literature (Chem. Eur. J. 2004.10.2011).

The compound A (10 g) was dissolved in water (300 mL) and a hydrochloric acid (17 mL), and cooled in an ice bath. Sodium nitrite (3.3 g) was added thereto, and stirring was performed for 30 minutes. After the addition of an amidosulfuric acid (0.5 g), m-toluidine (5.1 g) was added, and the resulting mixture was stirred at room temperature for 1 hour. After the stirring, the mixture was neutralized with a hydrochloric acid, and the obtained solid was collected by suction filtration to obtain a compound B (3.2 g).

The compound B (1 g) was dissolved in a THF solution containing tetrahydrofuran (30 mL, THF), water (10 mL), and a hydrochloric acid (1.6 mL), and cooled in an ice bath. Sodium nitrite (0.3 g) was added thereto, and stirring was performed for 30 minutes. Then, an amidosulfuric acid (0.5 g) was further added. Separately, phenol (0.4 g) was dissolved in potassium carbonate (2.76 g) and water (50 mL), and cooled in an ice bath, and the above-described THF solution was added dropwise thereto and stirred at room temperature for 1 hour. After the stirring, water (200 mL) was added, and the obtained compound C (1.7 g) was suction-filtered.

The compound C (0.6 g), the compound X (0.8 g), and potassium carbonate (0.95 g) were dissolved in DMAc (30 mL, dimethylacetamide) and stirred at 90° C. for 3.5 hours. After the stirring, water (300 mL) was added, and the obtained solid was suction-filtered to obtain a dichroic dye compound D1 (0.3 g).

[Synthesis of Dichroic Dye Compound D4]

First, according to the literature (Chem. Eur. J. 2004, 10, 2011-2021), a compound E was synthesized with the following route.

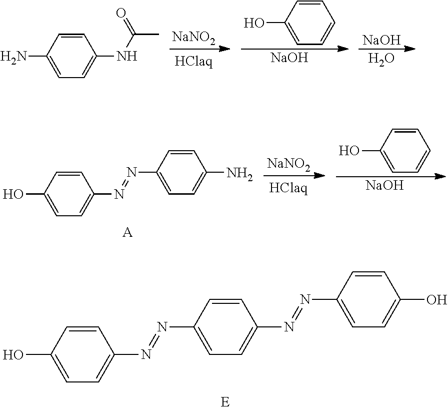

Next, a dichroic dye compound D4 was synthesized with the following route.

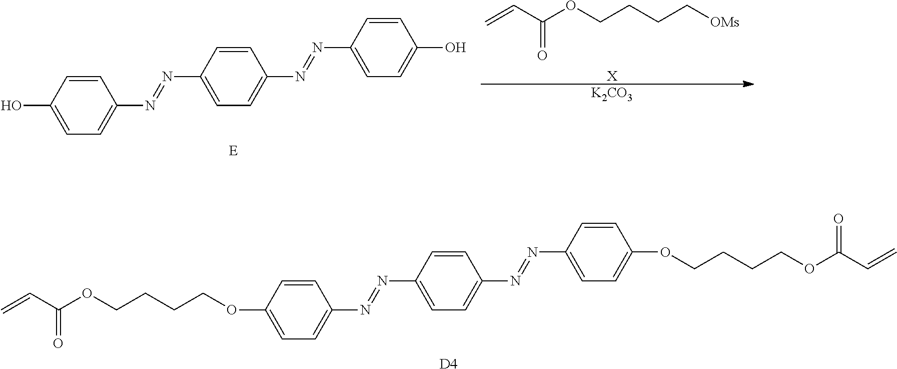

The compound E (0.3 g), the compound X (0.8 g), and potassium carbonate (0.95 g) were dissolved in DMAc (20 mL), and stirred at 90° C. for 3 hours. After the stirring, water (200 mL) was added, and the obtained solid was suction-filtered to obtain a dichroic dye compound 134 (0.1 g).

[Synthesis of Dichroic Dye Compounds D5 to D13]

Dichroic dye compounds D5 to D13 were synthesized with reference to the above-described method of synthesizing a dichroic dye compound D1 or D4. The structures of the dichroic dye compounds D1 and D4 to D13 will be collectively shown below.

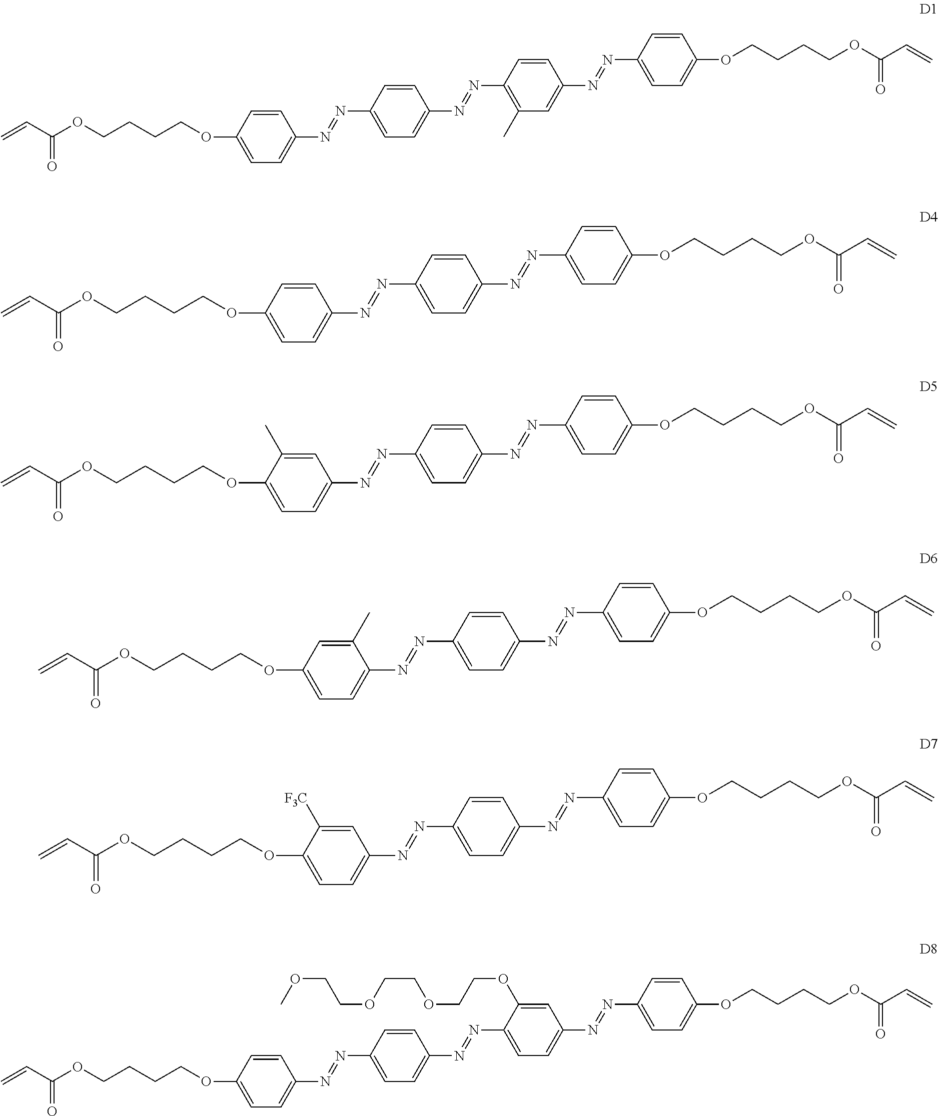

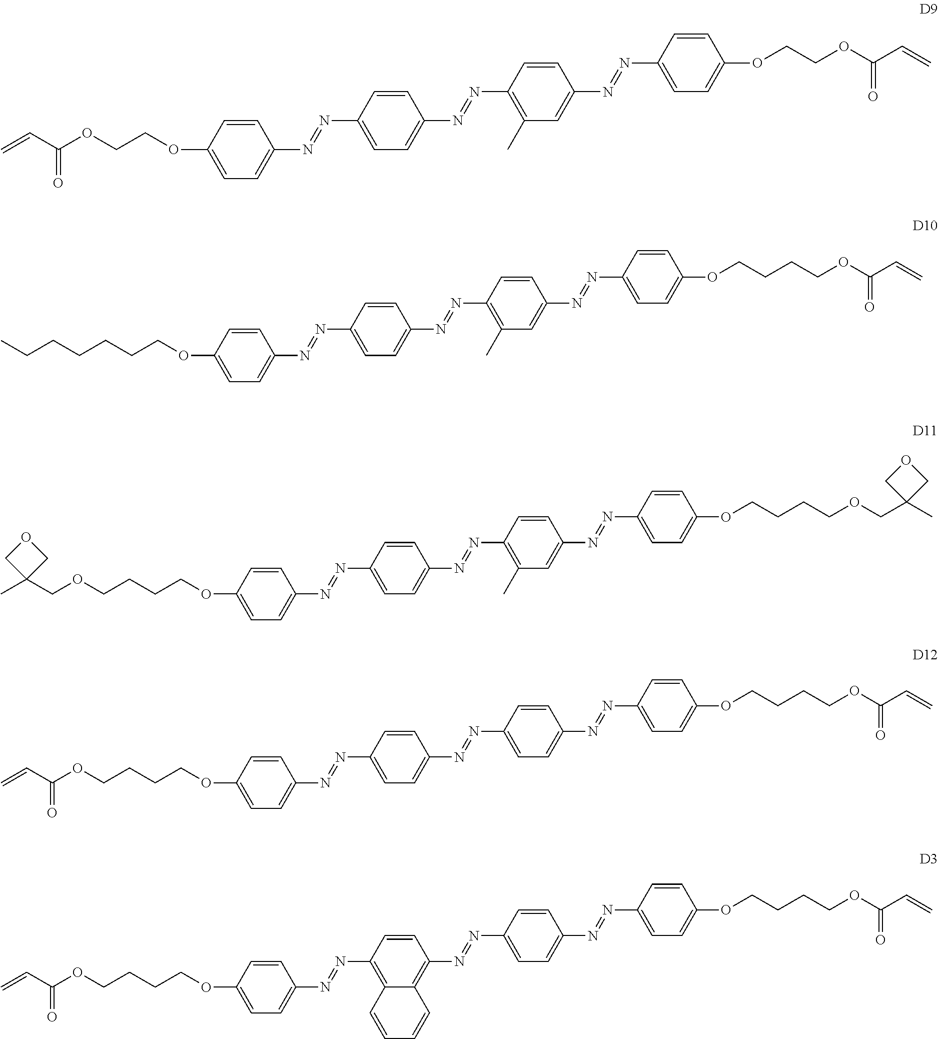

### Example 1

A light absorption anisotropic film was produced using a coloring composition of Example 1 to be described later on an alignment film produced as described below.

<Production of Alignment Film>

A glass base (manufactured by Central Glass Co., Ltd., blue plate glass, size: 300 mm×300 mm, thickness: 1.1 mm) was washed with an alkaline detergent, and then pure water was poured thereto. After that, the glass base was dried.

The following alignment film forming composition 1 was applied to the glass base after the drying using a bar #12, and the applied alignment film forming composition 1 was dried for 2 minutes at 110° C. to form a coating film on the glass base.

The obtained coating film was subjected to a rubbing treatment (rotation speed of roller: 1,000 rotations/2.9 mm, stage speed: 1.8 m/min) once to form an alignment film on the glass base.

Composition of Alignment Film Forming Composition 1

| | |
|---|---|
| •Modified Vinyl Alcohol (see Formula (PVA-1)) | 2.00 parts by mass |
| •Water | 74.16 parts by mass |
| •Methanol | 23.78 parts by mass |
| •Photopolymerization Initiator (IRGACURE 2959, manufactured by BASF SE) | 0.06 parts by mass |
| 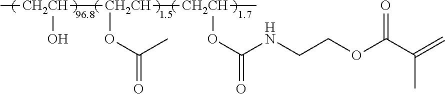 | (PVA-1) |

The obtained alignment film was spin-coated with a coloring composition of Example 1 (see the following composition) by using a spin coater at a rotation speed of 500 rotations/30 sec. Then, drying was performed for 30 seconds at room temperature to form a coating film. on the alignment film. Next, the obtained coating film was heated for 15 seconds at 120° C., and then cooled to room temperature to produce a light absorption anisotropic film of Example 1 on the alignment film.

Composition of Coloring composition of Example 1

| | |
|---|---|
| •Liquid Crystalline Compound P1 (sec Formula (P1)) | 2.33 parts by mass |
| •Dichroic Dye Compound D1 (see Formula (D1)) | 0.93 parts by mass |
| •Dichroic Dye Compound D2 (see Formula (D2)) | 0.77 parts by mass |
| •Dichroic Dye Compound D3 (see Formula (D3)) | 1.06 parts by mass |
| •Photopolymerization Initiator (IRGACURE 819, manufactured by BASF SE) | 0.37 parts by mass |
| •Interface Improver F1 (see Formula F1)) | 0.20 parts by mass |
| •Cyclopentanone (solvent) | 94.34 parts by mass |
| 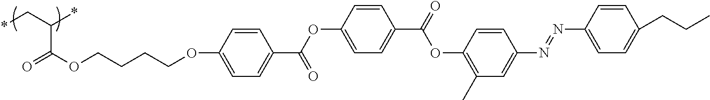 | P1 |
| 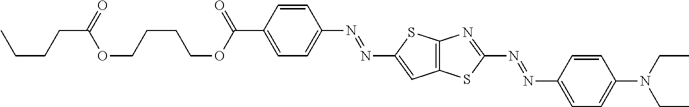 [SMILES: CCCCC(=O)OCCCCOC(=O)c1ccc(/N=N/c2cc3sc(/N=N/c4ccc(N(CC)CC)cc4)nc3s2)cc1] | D2 |
| 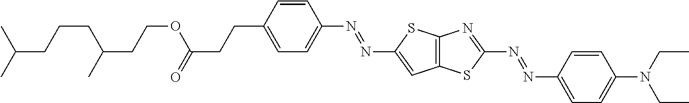 [SMILES: CCN(CC)c1ccc(/N=N/c2nc3sc(/N=N/c4ccc(CCC(=O)OCCC(C)CCCC(C)C)cc4)cc3s2)cc1] | D3 |
| 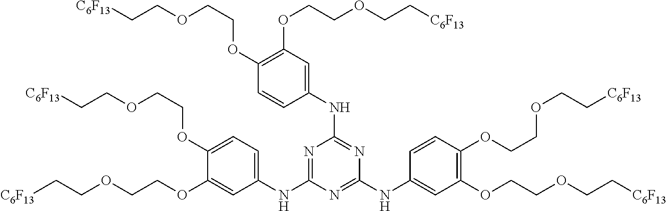 | F1 |

### Examples 2 to 9 and Comparative Examples 1 and 2

Light absorption anisotropic films of Examples 2 to 9 and Comparative Examples 1 and 2 were produced in the same manner as in Example 1, except that coloring compositions of Examples 2 to 9 and Comparative Examples 1 and 2 were used.

Here, the coloring compositions of Examples 2 to 9 and Comparative Examples 1 and 2 have the same composition as the coloring composition of Example 1, except that the dichroic dye compounds D4 to D13 were used instead of the dichroic dye compound D1 contained in the coloring composition of Example 1.

### Examples 10 to 17 and Comparative Example 3

Light absorption anisotropic films of Examples 10 to 17 and Comparative Example 3 were produced in the same manner as in Example 1, except that coloring compositions of Examples 10 to 17 and Comparative Example 3 were used.

Here, the coloring compositions of Examples 10 to 17 and Comparative Example 3 have the same composition as the coloring composition of Example 1, except that the following dichroic dye compounds D14 to D22 were used instead of the dichroic dye compound D1 contained in the coloring composition of Example 1.

In addition, the dichroic dye compounds D14 to D22 were synthesized with reference to the above-described method of synthesizing a dichroic dye compound D 1 or D4. The structures of the dichroic dye compounds D14 to D22 will be collectively shown below.

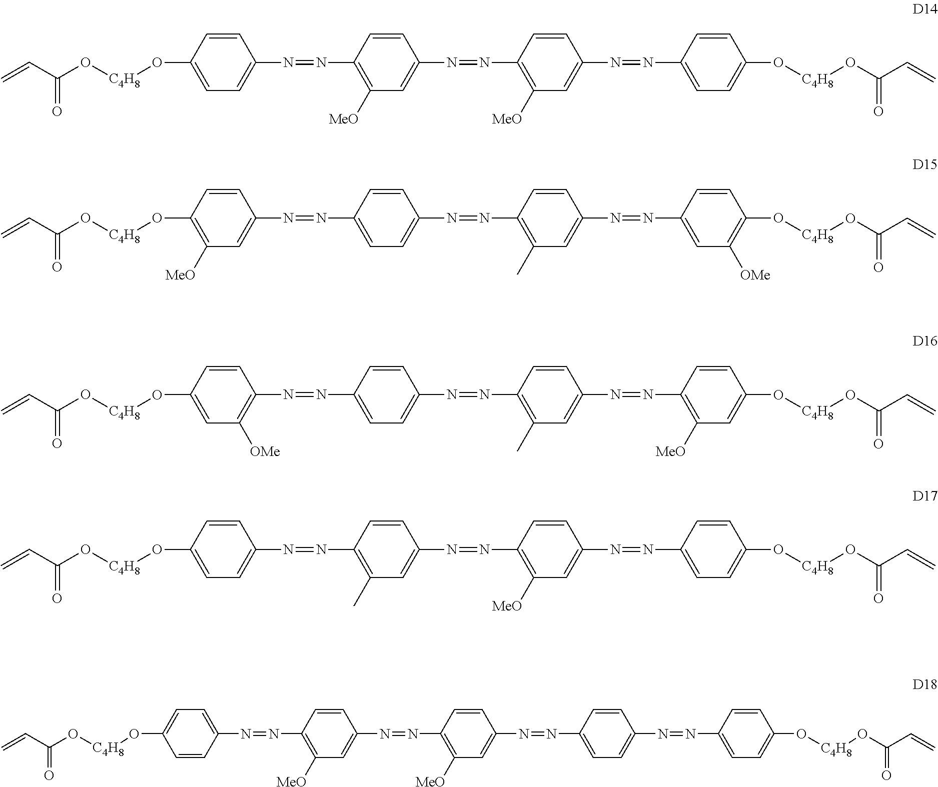

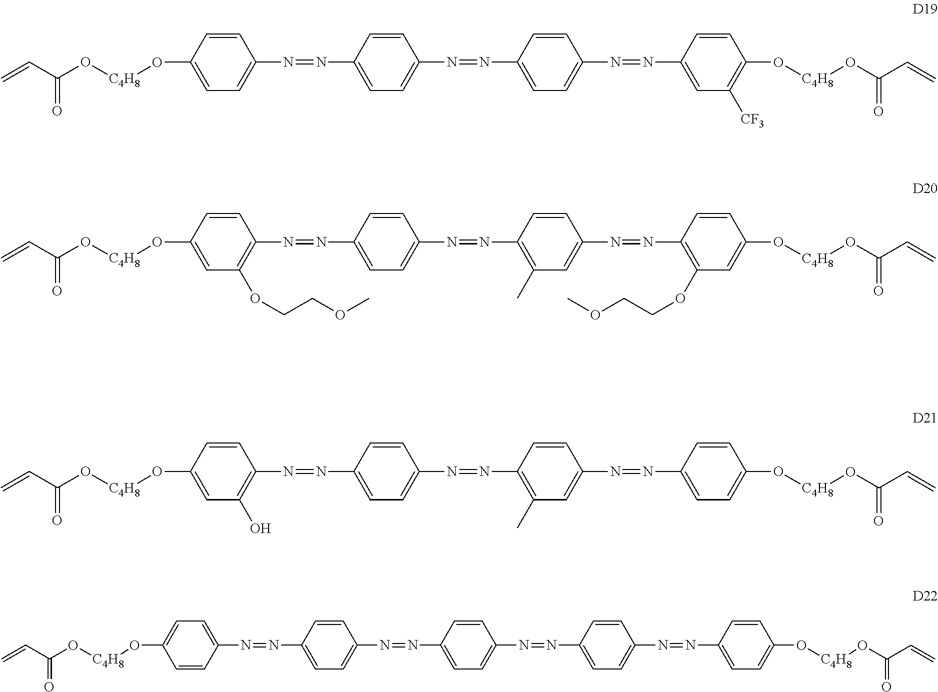

### Example 18 and Comparative Example 4

Light absorption anisotropic films of Example 18 and Comparative Example 4 were produced in the same manner as in Example 1, except that coloring compositions of Example 18 and Comparative Example 4 were used.

Here, the coloring compositions of Example 18 and Comparative Example 4 have the same composition as the coloring composition of Example 1, except that the following dichroic dye compounds D23 and D24 were used instead of the dichroic dye compound D1 contained in the coloring composition of Example 1.

In addition, the dichroic dye compounds D23 and D24 were synthesized with reference to the above-described method of synthesizing a dichroic dye compound D1 or D4. The structures of the dichroic dye compounds D23 and D24 will be collectively shown below.

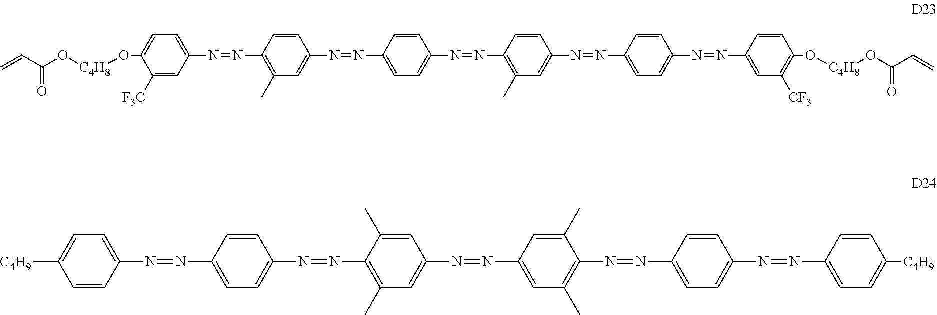

[Evaluation Test]

<Solubility of Dichroic Dye Compound>

The solubilities of the dichroic dye compounds D1 and D4 to D24 used in the examples and the comparative examples were measured as follows.

0.1 g of each dichroic dye compound was added to 2 g of cyclopentanone, and dissolved with ultrasonic waves. Then, 0.2 g of the solution portion was weighed and diluted with 45 g of cyclopentanone. The absorption spectrum of the cyclopentanone solution was measured to obtain an absorbance A (for solubility measurement).

Separately, 0.1 mg of each dichroic dye compound was completely dissolved in 100 g of cyclopentanone, and the absorption spectrum was measured to obtain an absorbance B (having a known concentration).

From data of the obtained two absorbances, the solubility was calculated by the following formula.

Solubility (mass %)=[(45+0.2)×A/(0.2×B×95.2×1,000)]×100

The evaluation standards are as follows.

A: The solubility is 2.5 mass % or greater.

B: The solubility is 1.0 mass % or greater and ess than 2.5 mass %.

C: The solubility is less than 1.0 mass %.

<Alignment Degree>

In a state in which a linear polarizer was inserted on the light source side of an optical microscope (manufactured by Nikon Corporation, product name “ECLIPSE E600 POL”), the light absorption anisotropic film of each of the examples and the comparative examples was set on a sample table, and using a multi-channel spectroscope (manufactured by Ocean Optics, Inc., product name “QE65000”), an absorbance of the light absorption anisotropic film in a wavelength band of 400 to 700 nm was measured to calculate an alignment degree by the following formula.

Alignment Degree: S=[(Az0/Ay0)−1]/[(Az0/Ay0)+2]

Az0: An absorbance with respect to the polarization in an absorption axis direction of the light absorption anisotropic film

Ay0: An absorbance with respect to the polarization in a polarization axis direction of the light absorption anisotropic film.

The evaluation standards are as follows.

A: The alignment degree is 0.85 or greater.

B: The alignment degree is 0.8 or greater and less than 0.85.

C: The alignment degree is less than 0.8.

[Evaluation Results]

The results of the above evaluation tests are shown in Table 1.

TABLE 1

| | Kind of Dichroic | Evaluation Results | | | |
|---|---|---|---|---|---|
| | Dye Compound | Solubility (wt %) | | Alignment Degree | |
| Example 1 | D1 | A | 4.5 | A | 0.86 |
| Example 2 | D4 | A | 5.7 | A | 0.88 |
| Example 3 | D5 | A | 6.8 | B | 0.83 |
| Example 4 | D6 | A | 18 | B | 0.84 |
| Example 5 | D7 | A | 42 | B | 0.82 |
| Example 6 | D8 | A | 4.8 | B | 0.83 |
| Example 7 | D9 | A | 4.3 | A | 0.88 |
| Example 8 | D10 | A | 2.8 | A | 0.87 |
| Example 9 | D11 | A | 3.3 | A | 0.86 |
| Comparative | D12 | C | 0.8 | A | 0.89 |
| Example 1 | | | | | |
| Comparative | D13 | B | 1.5 | C | 0.78 |
| Example 2 | | | | | |
| Example 10 | D14 | A | 3.1 | A | 0.85 |
| Example 11 | D15 | A | 4.3 | A | 0.85 |
| Example 12 | D16 | A | 5.0 | A | 0.85 |
| Example 13 | D17 | A | 3.2 | A | 0.86 |
| Example 14 | D18 | B | 2.1 | A | 0.86 |
| Example 15 | D19 | A | >5 | A | 0.87 |
| Example 16 | D20 | A | >5 | B | 0.83 |
| Example 17 | D21 | B | 1.5 | A | 0.86 |
| Comparative | D22 | C | 0.3 | A | 0.89 |
| Example 3 | | | | | |
| Example 18 | D23 | B | 1.2 | A | 0.91 |
| Comparative | D24 | C | <0.1 | A | 0.91 |
| Example 4 | | | | | |

As shown in Table 1, the dichroic dye compounds D1, D4 to D11, D14 to D21, and D23 having a structure represented by Formula (1) used in Examples 1 to 18 had excellent solubility.

From the comparison between Examples 2 to 5, it was found that in a case where a dichroic dye compound having a bisazo structure is used among dichroic dye compounds having a structure represented by Formula (1), and at least one of R₁, R₂, or R₃ is present therein (dichroic dye compounds D5 to D7 of Examples 3 to 5), the dichroic dye compound has more excellent solubility.

From the comparison between Examples 3 and 4 and the comparison between Example 11 and Example 12, it was found that in a case where at least one of R₁, R₂, or R₃ is positioned next to an azo group in a dichroic dye compound having a structure represented by Formula (1) (dichroic dye compound. D6 of Example 4 and dichroic dye compound D16 of Example 12), the dichroic dye compound has more excellent solubility.

From the comparison between Examples 3 and 5, it was found that in a case where a substituent present in R₁ to R₃ is a fluoroalkyl group in a dichroic dye compound having a structure represented by Formula (1) (dichroic dye compound D7 of Example 5), the dichroic dye compound has more excellent solubility.

From the comparison between Examples 1 and 6, it was found that in a case where a substituent present in R₁ to R₃ is —O—(C₂H₄O)m-R′ in a dichroic dye compound having a structure represented by Formula (1) (dichroic dye compound D8 of Example 6), the dichroic dye compound has more excellent solubility.

From the comparison between Examples 1 and 7, it was found that in a case where the number of atoms of the main chain of at least one of L₁ or L₂ is 5 or more in a dichroic dye compound having a structure represented by Formula (1) (dichroic dye compound D1 of Example 1), the dichroic dye compound has more excellent solubility.

From the comparison between Examples 1 and 8, it was found that in a case where both A and B are acryloyl groups or methacryl groups in a dichroic dye compound having a structure represented by Formula (1) (dichroic dye compound D1 of Example 1), the dichroic dye compound has more excellent solubility.

From the comparison between Examples 1 and 9, it was found that in a case where a crosslinkable group in A or B is an acryloyl group or a methacryl group in a dichroic dye compound having a structure represented by Formula (1) (dichroic dye compound D1 of Example 1), the dichroic dye compound has more excellent solubility.

As shown in Table 1, according to the coloring compositions of Examples 1 to 9, it was possible to produce a light absorption anisotropic film having an excellent alignment degree since the coloring compositions contained any one of the dichroic dye compound D1, D4, D5, D6, D7, D8, D9, D10, or D11 having a structure represented by Formula (1).

From the comparison between Examples 2 to 5, it was found that in a case where a dichroic dye compound having a bisazo structure is used among dichroic dye compounds having a structure represented by Formula (1), and none of R₁, R₂, and R₃ are present therein (dichroic dye compound D4 of Example 2), a light absorption anisotropic film having a more excellent alignment degree is obtained.

From the comparison between Examples 1 and 7, it was found that in a case where the number of atoms of the main chain of at least one of L₁ or L₂ is less than 5 in a dichroic dye compound having a structure represented by Formula (1) (dichroic dye compound D9 of Example 7), a light absorption anisotropic film having a more excellent alignment degree is obtained.

It was found that in Comparative Examples 1 to 4, the dichroic dye compound having a structure represented by Formula (1) is not contained, and thus the solubility of the dichroic dye compound or the alignment degree of the light absorption anisotropic film deteriorates.

### Example 19

The alignment film was spin-coated with the following coloring composition 19 by using a spin coater at a rotation speed of 1,000 rotations/30 sec. Then, drying was performed for 30 seconds at room temperature to form a coating film on the alignment film. Next, the obtained coating film was heated for 15 seconds at 135° C., and then cooled to room temperature, Next, the coating film was re-heated at 80° C., held for 30 seconds, and then cooled to room temperature, and thus a light absorption anisotropic film of Example 19 was produced on the alignment film.

Composition of Coloring Composition of Example 19

| | |
|---|---|
| •Liquid Crystalline Compound P2 (see Formula (P2)) | 4.012 parts by mass |
| •Dichroic Dye Compound D25 (see Formula (D25)) | 0.963 parts by mass |
| •Dichroic Dye Compound D1 (see Formula (D1)) | 0.792 parts by mass |
| •Interface Improver F2 (see Formula (F2)) | 0.073 parts by mass |
| •Interface Improver F3 (see Formula (F3)) | 0.073 parts by mass |
| •Interface Improver F4 (see Formula (F4)) | 0.087 parts by mass |
| •Tetrahydrofuran (solvent) | 79.90 parts by mass |
| •Cyclopentanone (solvent) | 14.10 parts by mass |
| 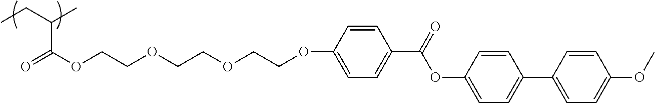 | P2 |
| 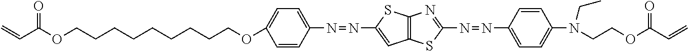 [SMILES: C=CC(=O)OCCCCCCCCCOc1ccc(N=Nc2cc3sc(N=Nc4ccc(N(CC)CCOC(=O)C=C)cc4)nc3s2)cc1] | D25 |
| 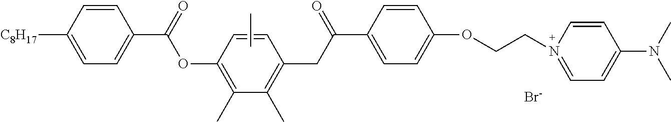 | F2 |
| 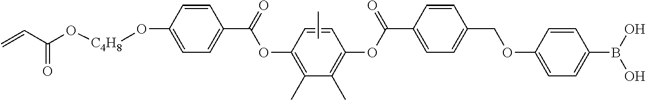 | F3 |
| 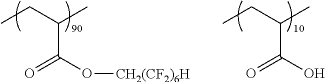 | F4 |

<Perpendicular Alignment Degree and Front Transmittance>

Using the light absorption anisotropic film of Example 19, the Mueller matrix of the light absorption anisotropic film at a wavelength λ was measured at intervals of 10° with varying polar angles of −50° to 50° in AxoScan OPMF-1 (manufactured by Opto Science, Inc.). The influence of surface reflection was removed, and then transmission efficiency ko [λ] and transmission efficiency ke [λ] were calculated by fitting the Mueller matrix to the following theoretical formula considering Snell's equation and Fresnel's equation. The wavelength λ is set to 550 nm unless otherwise noted.

k=−log(T)×λ/(4πd)

From the calculated ko [λ] and ke [λ], absorbances and dichroic ratios in an in-plane direction and in a thickness direction were calculated, and finally, a perpendicular alignment degree was obtained.

In addition, the measurement result at a polar angle of 0° in which the influence of surface reflection was removed was used as a front transmittance.

As a result, the light absorption anisotropic film of Example 19 had a perpendicular alignment degree of 0.92 and a front transmittance of 95%.

What is claimed is:

1. A coloring composition comprising:
a dichroic dye compound having a structure represented by Formula (1), 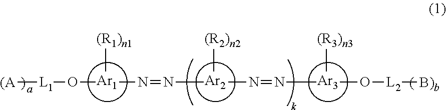
in Formula (1), A and B each independently represent a crosslinkable group,
in Formula (1), a and b each independently represent 0 or 1, and a+b is not less than 1,
in Formula (1), in a case where a is 0, L₁ represents a monovalent substituent, in a case where a is 1, L₁ represents a single bond or a divalent linking group, in a case where b is 0, L₂ represents a monovalent substituent, and in a case where b is 1, L₂ represents a single bond or a divalent linking group,
in Formula (1), Ar₁ represents a (n1+2)-valent aromatic hydrocarbon group or heterocyclic group, Ar₂ represents a (n2+2)-valent aromatic hydrocarbon group or heterocyclic group, and Ar₃ represents a (n3+2) -valent aromatic hydrocarbon group or heterocyclic group,
in Formula (1), R₁, R₂, and R₃ each independently represent a monovalent substituent, in a case where n1 is not less than 2, plural R₁'s may be the same or different, in a case where n2 is not less than 2, plural R₂'s may be the same or different, and in a case where n3 is not less than 2, plural R₃'s may be the same or different,
in Formula (1), k represents an integer of 1 to 4, and in a case where k is not less than 2, plural Ar₂'s may be the same or different, and plural R₂'s may be the same or different, and
in Formula (1), n 1, n2, and n3 each independently represent an integer of 0 to 4, in a case where k is 1, n1+n2+n3 is not less than 0, and in a case where k is not less than 2, n1+n2+n3 is not less than 1.

2. The coloring composition according to claim 1,
wherein in Formula (1), in a case where Ar₁, Ar₂, and Ar₃ have a condensed ring structure, all rings constituting the condensed ring structure are connected along a longitudinal direction of the structure represented by Formula (1).

3. The coloring composition according to claim 1,
wherein in a case where Formula (1) has at least one substituent selected from R₁, R₂ or R₃, at least one condition selected from the following condition (R1), (R2), or (R3) is satisfied,
Condition (R1): in Ar₁, at least one R₁ and an azo group are positioned next to each other,
Condition (R2): in Ar₂, at least one R₂ and at least one azo group arc positioned next to each other, and
Condition (R3): in Ar₃, at least one R₃ and an azo group are positioned next to each other.

4. The coloring composition according to claim 1,
wherein in a case where Formula (1) has at least one substituent selected from R₁, R₂ or R₃, the monovalent substituent represented by R₁, the monovalent substituent represented by R₂, and the monovalent substituent represented by R₃ each independently represent a halogen atom, a cyano group, a hydroxy group, an alkyl group, an alkoxy group, a fluorinated alkyl group, —O—(C₂H₄O)m-R′, —O—(C₃H₆O)m-R′, an alkylthio group, an oxycarbonyl group, a thioalkyl group, an acyloxy group, an acylamino group, an alkoxycarbonylamino group, a sulfonylamino group, a sulfamoyl group, a carbamoyl group, a sulfinyl group, or a ureido group, R′ represents a hydrogen atom, a methyl group, or an ethyl group, and m represents an integer of 1 to 6.

5. The coloring composition according to claim 1,
wherein in Formula (1), the number of atoms of a main chain of at least one of L₁ or L₂ is 3 or more.

6. The coloring composition according to claim 1,
wherein the crosslinkable group is an acryloyl group or a methacryloyl group.

7. The coloring composition according to claim 1, further comprising:
one or more kinds of dichroic dye compounds other than the dichroic dye compound having a structure represented by Formula (1).

8. A dichroic dye compound having a structure represented by Formula (1), 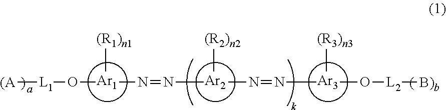
in Formula (1), A and B each independently represent a crosslinkable group,
in Formula (1), a and b each independently represent 0 or 1, and a+b is not less than 1,
in Formula (1), in a case where a is 0, L₁ represents a monovalent substituent, in a case where a is 1, L₁ represents a single bond or a divalent linking group, in a case where b is 0, L₂ represents a monovalent substituent, and in a case where b is 1, L₂ represents a single bond or a divalent linking group,
in Formula (1), Ar₁ represents a (n1+2)-valent aromatic hydrocarbon group or heterocyclic group, Ar₂ represents a (n2+2)-valent aromatic hydrocarbon group or heterocyclic group, and Ar₃ represents a (n3+2)-valent aromatic hydrocarbon group or heterocyclic group,
in Formula (1), R₁, R₂, and R₃ each independently represent a monovalent substituent, in a case where n1 is not less than 2, plural R₁'s may be the same or different, in a case where n2 is not less than 2, plural R₂'s may be the same or different, and in a case where n3 is not less than 2, plural R₃'s may be the same or different,
in Formula (1), k represents an integer of 1 to 4, and in a case where k is not less than 2, plural Ar₂'s may be the same or different, and plural R₂'s may be the same or different, and
in Formula (1), n1, n2, and n3 each independently represent an integer of 0 to 4, in a case where k is 1, n1+n2+n3 is not less than 0, and in a case where k is not less than 2, n1+n2+n3 is not less than 1.

9. The dichroic dye compound n according to claim 8,
wherein in Formula (1), in a case where Ar₁, Ar₂, and Ar₃ have a condensed ring structure, all rings constituting the condensed ring structure are connected along a longitudinal direction of the structure represented by Formula (1).

10. The dichroic dye compound according to claim 8,
wherein in a case where Formula (1) has at least one substituent selected from R₁, R₂ or R_{3,} at least one condition selected from the following condition (R1), (R2), or (R₃) is satisfied,
Condition (R1): in Ar₁, at least one R₁ and an azo group are positioned next to each other,
Condition (R2): in Ar₂, at least one R₂ and at least one azo group are positioned next to each other, and
Condition (R₃): in Ar₃, at least one R₃ and an azo group are positioned next to each other.

11. The dichroic dye compound according to claim 8,
wherein in a case where Formula (1) has at least one substituent selected from R₁, R₂ or R₃, the monovalent substituent represented by R₁, the monovalent substituent represented by R₂, and the monovalent substituent represented by R₃ each independently represent a halogen atom, a cyano group, a hydroxy group, an alkyl group, an alkoxy group, a fluorinated alkyl group, —O—(C₂H₄O)m-R′, —O—(C₃H₆O)m-R′, an alkylthio group, an oxycarbonyl group, a thioalkyl group, an acyloxy group, an acylamino group, an alkoxycarbonylamino group, a sulfonylamino group, a sulfamoyl group, a carbamoyl group, a sulfinyl group, or a ureido group, R′ represents a hydrogen atom, a methyl group, or an ethyl group, and in represents an integer of 1 to 6.

12. The dichroic dye compound according to claim 8,
wherein in Formula (1), the number of atoms of a main chain of at least one of L₁ or L₂ is 3 or more.

13. The dichroic dye compound according to claim 8,
wherein the crosslinkable group is an acryloyl group or a methaeryloyl group.

14. A light absorption anisotropic film which is formed using the coloring composition according to claim 1.

15. A laminate comprising:
a base; and
the light absorption anisotropic film according to claim 14 which is formed on the base.

16. The laminate according to claim 15, further comprising:
a λ/4 plate which is formed on the light absorption anisotropic film.

17. The laminate according to claim 15, further comprising:
an oxygen blocking layer which is formed on the light absorption anisotropic film.

18. An image display device comprising:
the light absorption anisotropic film according to claim 14.

19. The coloring composition according to claim 2,
wherein in a case where Formula (1) has at least one substituent selected from R₁, R₂ or R₃, at least one condition selected from the following condition (R1), (R2), or (R3) is satisfied,
Condition (R1): in Ar₁, at least one R₁ and an azo group are positioned next to each other,
Condition (R2): in Ar₂, at least one R₂ and at least one azo group are positioned next to each other, and
Condition (R3): in Ar₃, at least one R₃ and an azo group are positioned next to each other.

20. An image display device comprising:
the laminate according to claim 15.
